(19) United States
(12) Patent Application Publication
(10) Pub. No.: US 2018/0226611 A1
(43) Pub. Date: Aug. 9, 2018

(54) DISPLAY DEVICE

(71) Applicant: Japan Display Inc., Tokyo (JP)

(72) Inventors: Naohisa ANDOU, Tokyo (JP); Kenji TORIBATAKE, Tokyo (JP)

(21) Appl. No.: 15/875,070

(22) Filed: Jan. 19, 2018

(30) Foreign Application Priority Data
Feb. 3, 2017 (JP) 2017-018606

(51) Int. Cl. H01L 51/52; H01L 51/56; H01L 51/00; H01L 27/32

(52) U.S. Cl. CPC H01L 51/5253; H01L 51/56; H01L 27/3276; H01L 27/3265; H01L 51/0097

(57) ABSTRACT

Disclosed is a display device including: a substrate having a display region including a plurality of pixels, a terminal region including a terminal, and a wiring region between the display region and the terminal region, the wiring region including a wiring extending from the terminal to the display region; a first base film on an opposite side of the substrate from the plurality of pixels and under the display region; and a second base film on the opposite side of the substrate from the plurality of pixels and under the terminal region, the second base film being spaced from the first base film, where the first base film has a side surface facing the second base film and having a tapered portion.

### CROSS REFERENCE TO RELATED APPLICATIONS

This application is based on and claims the benefit of priority from the prior Japanese Patent Application No. 2017-018606, filed on Feb. 3, 2017, the entire contents of which are incorporated herein by reference.

### FIELD

An embodiment of the present invention relates to a flexible display device and a manufacturing method thereof. For example, an embodiment of the present invention relates to a flexible display device having high reliability and a method for manufacturing the display device at a high yield.

### BACKGROUND

A liquid crystal display device and an organic EL display device are represented as a typical example of a display device. These display devices have a plurality of pixels over a substrate, and a display element such as a liquid crystal element or an organic EL (Electroluminescence) element (hereinafter, referred to as a light-emitting element) is disposed in each pixel. A liquid crystal element and a light-emitting element respectively possess, between a pair of electrodes, a layer including a compound exhibiting a liquid crystallinity and a layer (hereinafter, referred to as an EL layer) including an organic compound exhibiting a light-emitting property and are operated by applying a voltage or supplying a current between the pair of electrodes.

A so-called flexible display (sheet display) capable of being bent or folded can be produced by providing flexibility to a substrate of a display device. For example, Japanese Patent Application Publication No. 2016-31499 and US Patent Application Publication No. 2016/0174304 disclose an organic EL display device prepared by using a flexible substrate. This display device has a display region and a terminal region including terminals for inputting image signals from outside and can be folded between the display region and the terminal region.

### SUMMARY

An embodiment according to the present invention is a display device including: a substrate having a display region including a plurality of pixels, a terminal region including a terminal, and a wiring region between the display region and the terminal region, the wiring region including a wiring extending from the terminal to the display region; a first base film on an opposite side of the substrate from the plurality of pixels and under the display region; and a second base film on the opposite side of the substrate from the plurality of pixels and under the terminal region, the second base film being spaced from the first base film, where the first base film has a side surface facing the second base film and having a tapered portion.

An embodiment according to the present invention is a display device including: a flexible substrate having a first region including a plurality of pixels and a second region spaced from the first region, the first region overlapping with the second region; a first base film in the first region and on an opposite side of the substrate from the plurality of pixels; and a second base film in the second region and on the opposite side of the substrate from the plurality of pixels, where the first base film and the second base film are sandwiched between the first region and the second region, and the first base film has a side surface overlapping with the second region and having a tapered portion.

An embodiment according to the present invention is a manufacturing method of a display device. The manufacturing method includes: forming a base-material film over a supporting substrate including a display region, a wiring region, and a terminal region; forming a pixel, a wiring, and a terminal in the display region, the wiring region, and the terminal region, respectively; forming a cap film over the display region; forming a base film having an opening portion under the base-material film so that the opening portion overlaps with the wiring region; and dividing the base film into a first base film overlapping with the display region and a second base film overlapping with the terminal region by trimming the base-material film. The wiring is configured to electrically connect the pixel to the terminal. A sidewall of the opening portion is inclined from an upper surface of the base film.

### BRIEF DESCRIPTION OF DRAWINGS

FIG. 1 is a schematic perspective view of a display device according to an embodiment;

FIG. 2 is a schematic top view of a display device according to an embodiment;

FIG. 3 is a schematic bottom view of a display device according to an embodiment;

FIG. 4A and FIG. 4B are schematic side views of a display device according to an embodiment;

FIG. 5A to FIG. 5C are schematic side views of a display device according to an embodiment;

FIG. 6A to FIG. 6C are schematic side views of a display device according to an embodiment;

FIG. 7A and FIG. 7B are schematic perspective views of a first or second base film of a display device according to an embodiment;

FIG. 8A to FIG. 8D are schematic perspective views of a first or second base film of a display device according to an embodiment;

FIG. 9 is a schematic top view for explaining a manufacturing method of a display device according to an embodiment;

FIG. 10 is a schematic top view of a display device according to an embodiment;

FIG. 11A to FIG. 11D are schematic side views for explaining trimming of a display device

FIG. 12 is a schematic top view for explaining a manufacturing method of a display device according to an embodiment;

FIG. 13 is a schematic top view for explaining a manufacturing method of a display device according to an embodiment;

FIG. 14 is a schematic cross-sectional view for explaining a manufacturing method of a display device according to an embodiment;

FIG. 15A to FIG. 15C are schematic cross-sectional views for explaining a manufacturing method of a display device according to an embodiment;

FIG. 16A to FIG. 16C are schematic cross-sectional views for explaining a manufacturing method of a display device according to an embodiment;

FIG. 17A and FIG. 17B are schematic cross-sectional views for explaining a manufacturing method of a display device according to an embodiment;

FIG. 18A and FIG. 18B are schematic cross-sectional views for explaining a manufacturing method of a display device according to an embodiment;

FIG. 19A and FIG. 19B are schematic cross-sectional views for explaining a manufacturing method of a display device according to an embodiment;

FIG. 20A and FIG. 20B are schematic cross-sectional views for explaining a manufacturing method of a display device according to an embodiment;

FIG. 21 is a schematic top view for explaining a manufacturing method of a display device according to an embodiment;

FIG. 22 is a schematic top view for explaining a manufacturing method of a display device according to an embodiment;

FIG. 23 is a schematic cross-sectional view for explaining a manufacturing method of a display device according to an embodiment;

FIG. 24A and FIG. 24B are respectively schematic top and cross-sectional views for explaining a manufacturing method of a display device according to an embodiment;

FIG. 25A and FIG. 25B are respectively schematic bottom and side views for explaining a manufacturing method of a display device according to an embodiment;

FIG. 26A is a schematic top view and FIG. 26B and FIG. 26C are schematic cross-sectional views for explaining a manufacturing method of a base film according to an embodiment;

FIG. 27A is a schematic top view and FIG. 27B and FIG. 27C are schematic cross-sectional views for explaining a manufacturing method of a base film according to an embodiment;

FIG. 28A is a schematic top view and FIG. 28B to FIG. 28D are schematic cross-sectional views for explaining a manufacturing method of a base film according to an embodiment;

FIG. 29A is a schematic top view and FIG. 29B to FIG. 29D are schematic cross-sectional views for explaining a manufacturing method of a base film according to an embodiment;

FIG. 30A and FIG. 30B are respectively schematic top and cross-sectional views for explaining a manufacturing method of a base film according to an embodiment; and

FIG. 31A and FIG. 31B are schematic cross-sectional views for explaining a manufacturing method of a base film according to an embodiment.

### DESCRIPTION OF EMBODIMENTS

An object of an embodiment according to the present invention is to provide a flexible display device and a manufacturing method thereof. For example, an object of an embodiment according to the present invention is to provide a method which enables production of a flexible display device at a high yield and a display device manufactured with the method.

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

### 1. Outline Structure

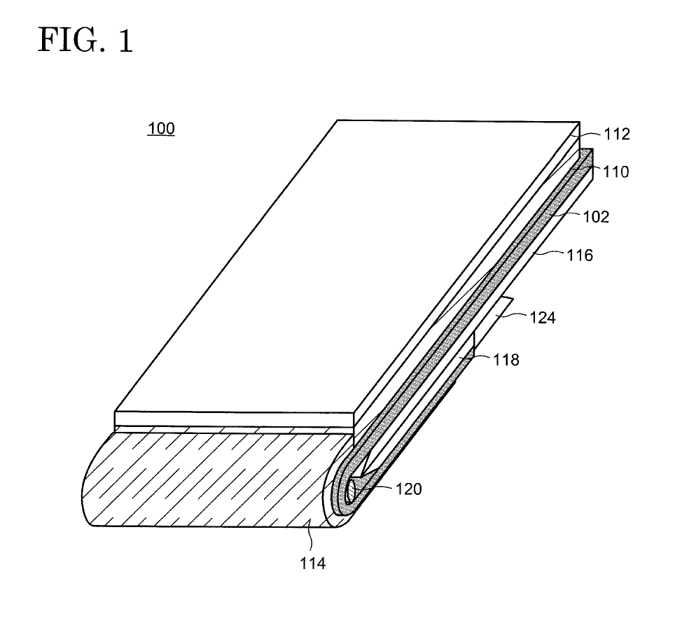

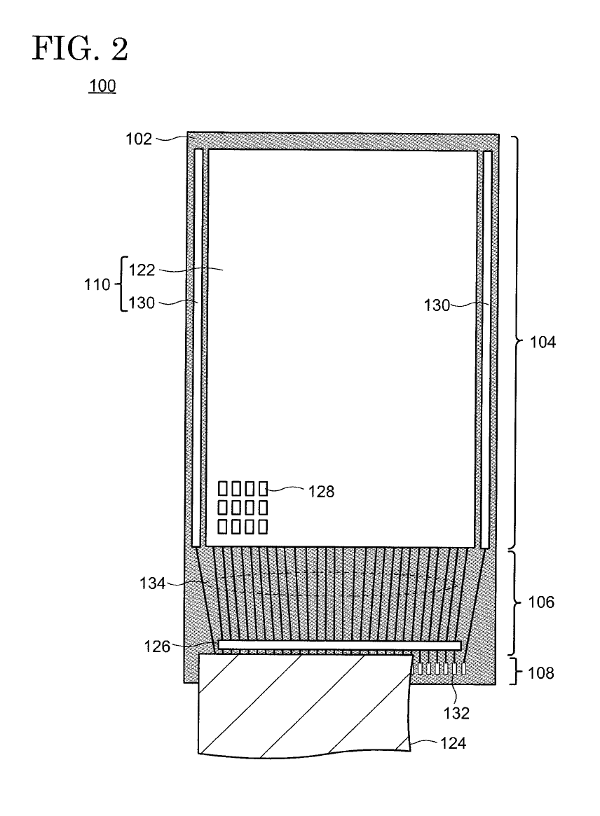

Schematic perspective and top views of a display device 100 according to the present embodiment are respectively shown in FIG. 1 and FIG. 2. As shown in FIG. 1, the display device 100 has a flexible substrate 102 and can be bent or folded. The flexible substrate 102 is also called a base material or a base-material film. An element layer 110 is provided over the flexible substrate 102. As described below, a variety of insulating films, conductive films, and semiconductor films is stacked in the element layer 110, by which transistors, capacitors, display elements, and the like constructing pixels and driver circuits are fabricated. A cap film 112 is disposed over the element layer 110 so that the element layer 110 is protected and physical strength is provided to the display device 100 to facilitate handling while maintaining sufficient flexibility. The cap film 112 has flexibility. Although not shown, the display device 100 may possess a polarizing plate, a touch sensor, and the like over the cap film 112 as an optional structure. Alternatively, a polarizing plate or a touch sensor may serve as the cap film 112.

A first base film 116 and a second base film 118 are arranged under the flexible substrate 102, that is, on a side of the flexible substrate 102 opposite to the element layer 110, to protect the flexible substrate 102 and provide physical strength thereto. The former and the cap film 112 sandwich the element layer 110 and the flexible substrate 102.

FIG. 2 is a drawing after developing the display device 100 in a folded state shown in FIG. 1 and illustrates an upper surface of the display device 100. The cap film 112 and a resin film 114 described below are omitted in FIG. 2 for visibility. The flexible substrate 102 can be demarcated into three regions (an active region (also called an active area) 104, a wiring region 106, and a terminal region 108). In other words, the flexible substrate 102 includes the active region 104, the wiring region 106, and the terminal region 108. The wiring region 106 is positioned between the active region 104 and the terminal region 108.

The element layer 110 is included in the active region 104 and structures a display region 122, driver circuits 130, and the like. A plurality of pixels 128 is arranged in a matrix form in the display region 122 and is controlled by the driver circuits 130. A display element is provided in each of the plurality of pixels 128. Although the display device 100 shown in FIG. 2 possesses two driver circuits 130, the number of the driver circuits 130 is not limited. The driver circuits 130 may not be formed in the active region 104 but may be mounted over the wiring region 106 or a connector 124.

A plurality of wirings 134 are disposed in the wiring region 106. The wirings 134 extend from the display region 122 and the driver circuits 130 and are connected to an IC chip 126. The wirings 134 further extend from the IC chip 126 to the terminal region 108 and are exposed at an edge portion to form terminals 132. The terminals 132 are connected to the connector 124 such as a FPC (flexible printed circuit) substrate. Image signals are input to the IC chip 126 and the driver circuits 130 from an external circuit which is not illustrated. Signals for controlling the pixels 128 are provided from the IC chip 126 and the driver circuits 130 on the basis of the image signals, by which an image is displayed on the display region 122. Note that the IC chip 126 is an optional structure, and a driver circuit may be formed over the active region 104 instead of the IC chip 126. The IC chip 126 may be mounted over the connector 124.

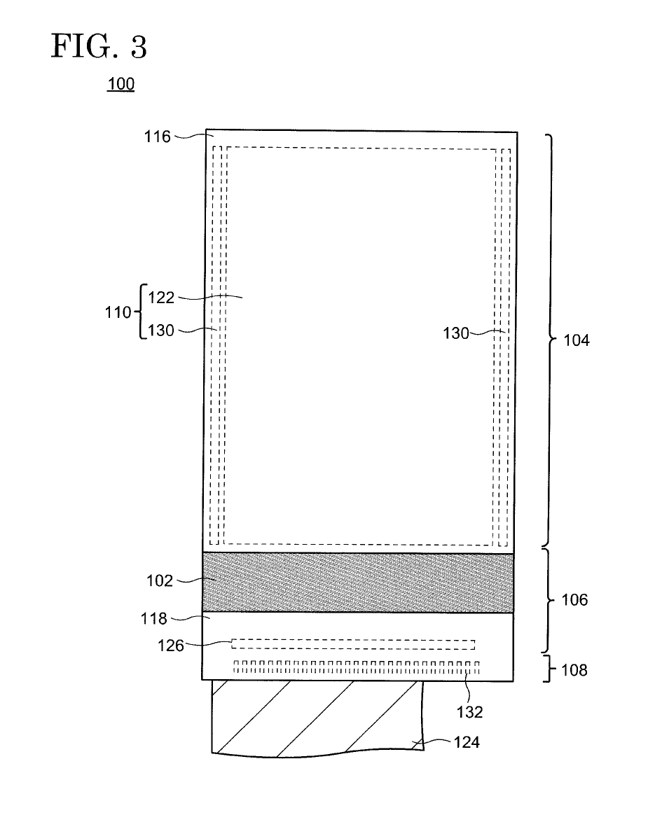

A bottom view of the display device 100 in the developed state is shown in FIG. 3. The first base film 116 is arranged so as to overlap with the active region 104 as well as the display region 122 and the driver circuits 130 in the active region 104. The second base film 118 is disposed so as to be spaced from the first base film 116 and overlap with the terminals 132 and the terminal region 108 including the terminals 132. The second base film 118 may overlap with a part of the wiring region 106 so as to overlap with the wirings 134 and the IC chip 126. A bottom surface of the flexible substrate 102 is exposed between the first base film 116 and the second base film 118.

The wiring region 106 in which the bottom surface of the flexible substrate 102 is exposed is more flexible than the active region 104 and the terminal region 108 to which the cap film 112, the first base film 116, and the second base film 118 are provided. Therefore, selective deformation of the wiring region 106 enables the display device 100 to be readily deformed into the folded shape shown in FIG. 1. In this shape, a part of the flexible substrate 102 overlaps with another part thereof. for example, the active region 104 including the display region 122 and the driver circuits 130 overlaps with the terminal region 108 and a part of the wiring region 106. The cap film 112 is located over the active region 104 and covers the display region 122 and the driver circuits 130. The second base film 118 is positioned over the first base film 116, and they are sandwiched by the active region 104 and the terminal region 108 of the flexible substrate 102. An undersurface of the first base film 116 and an undersurface of the second base film 118 may contact each other directly or through an adhesion layer which is not illustrated. Note that, although not shown, the region used to bend or fold the flexible substrate 102 is not limited to between the first base film 116 and the second base film 118, and the display device 100 may be bent or folded by using the active region 104.

The display device 100 may possess, as an optional structure, a spacer 120 along a bending axis of the flexible substrate 102. The spacer 120 may have a columnar shape, for example, and can be enclosed in a space surrounded by the flexible substrate 102, the first base film 116, and the second base film 118. Although not shown, the spacer 120 may further possess a plate-shaped portion. In this case, the display device 100 may be folded so that the plate-shaped portion is sandwiched by the first base film 116 and the second base film 118. The three-dimensional shape of the display device 100 can be controlled and stabilized by using the spacer 120.

### 2. Base Film

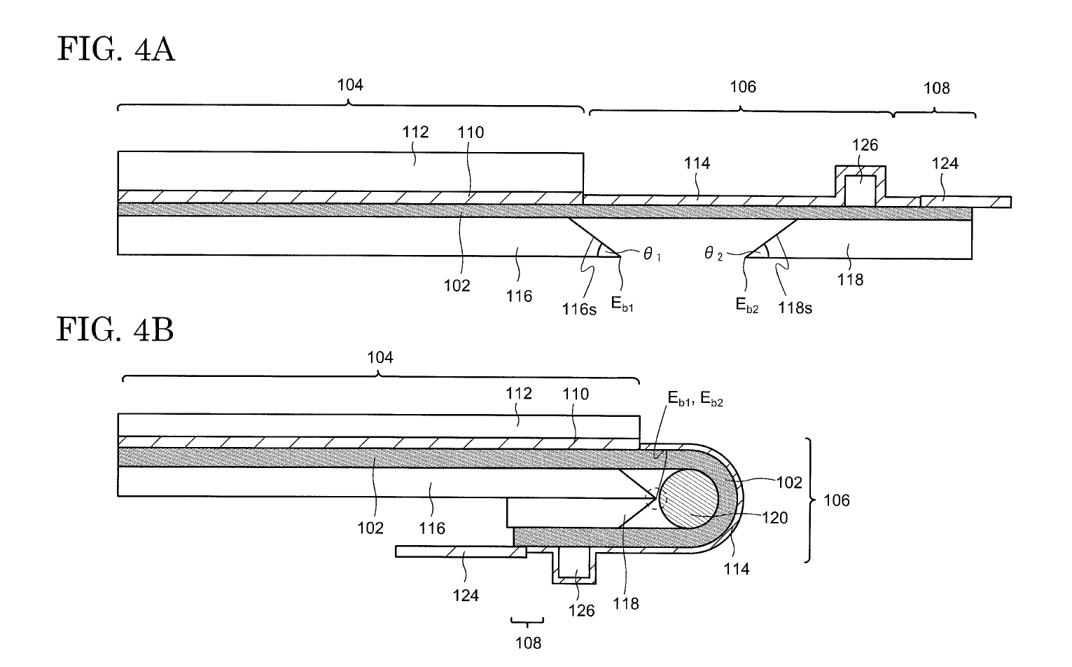

As shown in FIG. 1, an edge portion of the first base film 116 and an edge portion of the second base film 113 may each have a tapered shape. A detailed structure thereof is shown in FIG. 4A and FIG. 4B. FIG. 4A and FIG. 4B are side views of the display device 100 in the developed state and the folded state, respectively. As described above, the element layer 110 and the flexible substrate 102 are sandwiched by the cap film 112 and the first base film 116. The wirings 134 which are not illustrated here are covered by the resin film 114. The resin film 114 is illustrated so as to cover an upper surface of the IC chip 126 in FIG. 4A and FIG. 4B. However, the resin film 114 may not cover the IC chip 126. In addition, the resin film 114 may cover a part of the connector 124.

As shown in FIG. 4A, a side surface 116s of the first base film 116 facing the second base film 118 or the wiring region 106 is inclined from an upper surface of the first base film 116 so that the edge portion of the first base film 116 has a tapered shape. An edge portion having such a tapered shape is called a tapered portion. The tapered portion is configured so that a distance between the side surface 116s and the flexible substrate 102 increases from the active region 104 in the direction of the terminal region 108. That is, the tapered portion is formed so that a bottom surface of the first base film 116 is larger than the upper surface thereof.

In a similar way, a side surface 118s of the second base film 118 facing the first base film 116 or the wiring region 106 may have a tapered portion. The side surface 118s of this tapered portion is inclined from an upper surface of the second base film 118. The side surface 118s of the tapered portion is configured so that a distance between the side surface 118s and the flexible substrate 102 increases from the terminal region 108 in a direction of the active region 104. That is, the tapered portion is formed so that a bottom surface of the second base film 118 is larger than the upper surface thereof. Here, the upper surfaces of the first base film 116 and the second base film 118 mean the surfaces thereof in contact with the flexible substrate 102. The bottom surfaces of the first base film 116 and the second base film 118 mean the surfaces thereof opposite to the flexible substrate 102.

An angle θ₁ between the side surface 116s and the bottom surface of the first base film 116 and an angle θ₂ between the side surface 118s and the bottom surface of the second base film 118 can be independently determined. The angles θ₁ and θ₂ may be independently selected from a range of more than 0° and less than 90° (i.e., an acute angle), equal to or more than 15° and equal to or less than 60°, or equal to or more than 30° and equal to or less than 45°.

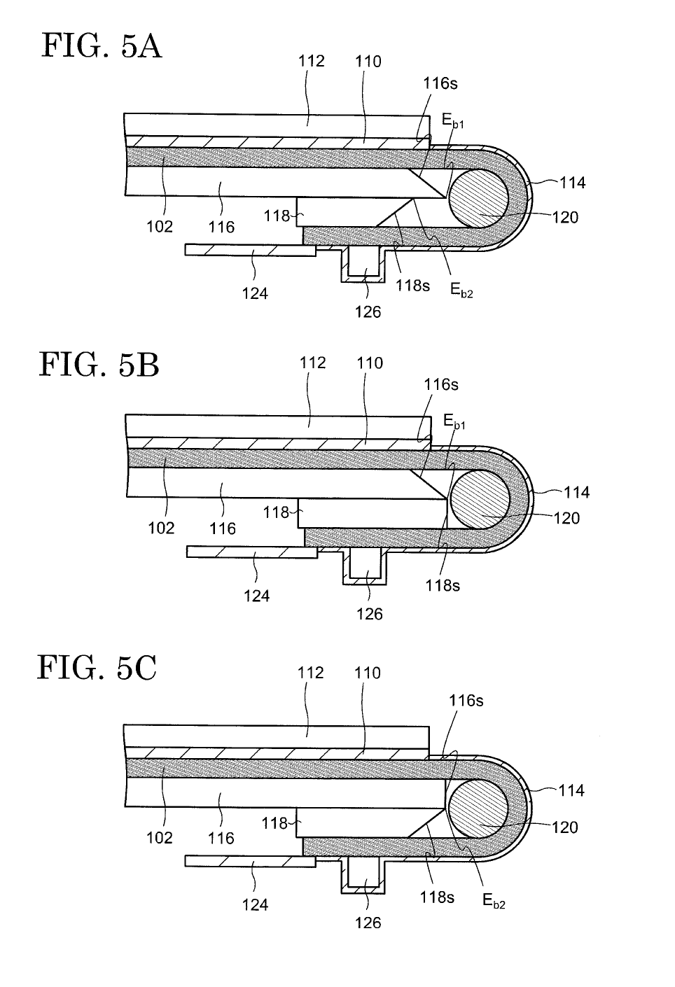

When the display device 100 is folded, the flexible substrate 102 may be deformed so that a tip E_{b1} of the tapered portion of the first base film 116 and a tip E_{b2} of the tapered portion of the second base film 118 are in contact with each other as shown in FIG. 4B (see the region surrounded by a dotted circle). However, the three-dimensional shape of the display device 100 may be arbitrarily determined. For example, the tips of the tapered portions of the first base film 116 and the second base film 118 may not contact each other but the latter may be in contact with the bottom surface of the first base film 116 as shown in FIG. 5A. Although not illustrated, the display device 100 may be deformed so that the former is in contact with the bottom surface of the second base film 118.

At least one of the first base film 116 and the second base film 118 may have the edge portion including the tapered portion. For example, the display device 100 may be configured so that the side surface 116s is inclined from the upper surface of the first base film 116 while the side surface 118s is perpendicular to the upper surface of the second base film 118 as shown in FIG. 5B. That is, the edge portion of the second base film 118 may not have the tapered shape, but the side surface 118s may be composed of a vertical portion perpendicular to the upper surface of the second base film 118. Alternatively, the display device 100 may be configured so that the side surface 118s is inclined from the upper surface of the second base film 118 while the side surface 116s is perpendicular to the upper surface of the first base film 116 as shown in FIG. 5C. Namely, the edge portion of the first base film 116 may not have the tapered portion, but the side surface 116s may be composed of a vertical portion perpendicular to the upper surface of the first base film 116.

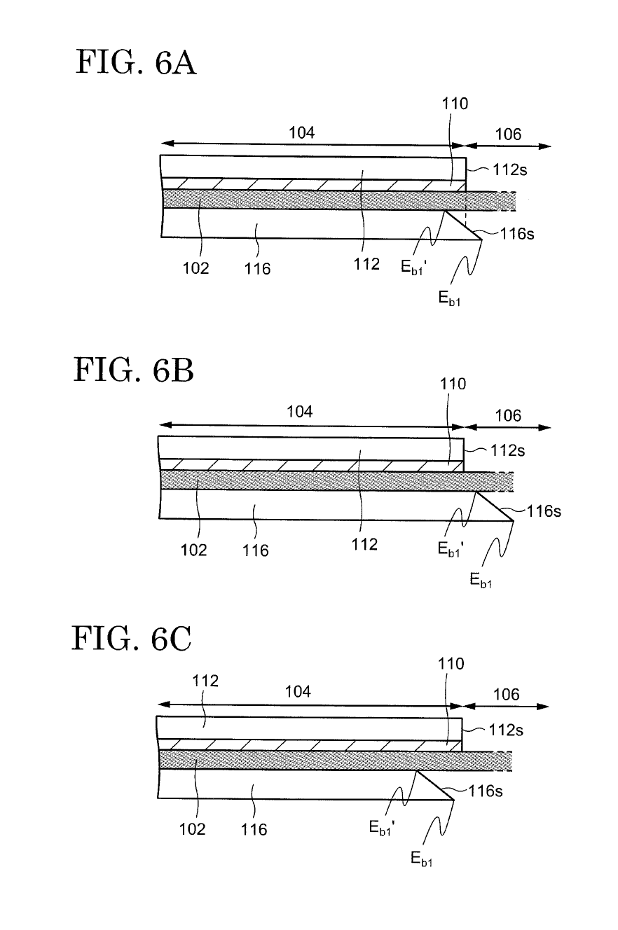

A positional relationship between the side surface 116s and the cap film 112 is shown in FIG. 6A to FIG. 6C. As shown in FIG. 6A, the first base film 116 may be arranged so that a side surface 112s of the cap film 112 facing the wiring region 106 overlaps with the side surface 116s. In this case, the tip E_{b1} of the side surface 116s does not overlap with the cap film 112. Furthermore, in a side view of the display device 100 or a cross-sectional view thereof along a line extending from the active region 104 to the wiring region 106, a cross point E_{b1}′ of the side surface 116s with the bottom surface of the flexible substrate 102 overlaps with the cap film 112.

Alternatively, the first base film 116 may be arranged so that the side surface 112s does not overlap with the side surface 116s but overlaps with the upper surface of the base film 116 as shown in FIG. 6B. In this case, the tip E_{b1} does not overlap with the cap film 112. Similarly, in a side view of the display device 100 or a cross-sectional view thereof along a line extending from the active region 104 to the wiring region 106, the cross point E_{b1}′ does not overlap with the cap film 112.

Alternatively, the first base film 116 may be arranged so that the side surface 116s overlaps with the upper surface and the bottom surface of the cap film 112 as shown in FIG. 6C. In this case, the tip E_{b1} overlaps with the cap film 112. Similarly, in a side view of the display device 100 or a cross-sectional view thereof along a line extending from the active region 104 to the wiring region 106, the cross point E_{b1}′ also overlaps with the cap film 112.

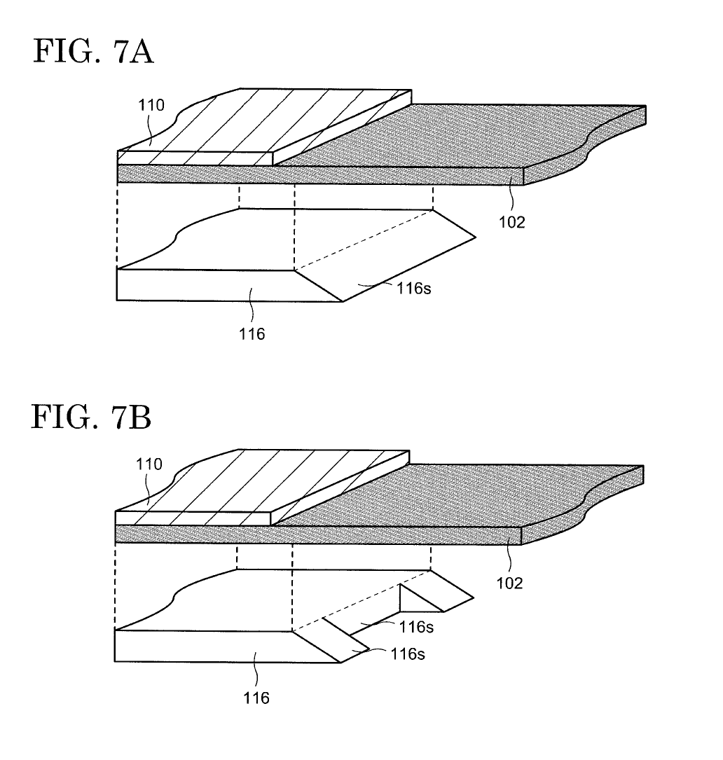

A perspective view of the first base film 116 is shown in FIG. 7A and FIG. 7B. In these figures, the first base film 116 and the flexible substrate 102 are separately illustrated for visibility. As shown in FIG. 7A, the tapered portion may be formed in the entire side surface 116s. Alternatively, the side surface 116s may have both a tapered portion and a vertical portion (or non-tapered portion) as shown in FIG. 7B. In this case, the first base film 116 may be configured so that two tapered portions sandwich the vertical portion (or non-tapered portion). Although not illustrated, the same can be applied to the edge portion of the second base film 118. As described above, the tapered portion means a portion of the edge portion having a tapered shape, while the vertical portion means a portion of the edge portion where the side surface is perpendicular to the upper surface. Note that a non-tapered portion may be provided instead of the vertical portion. An angle between the side surface 116s of the non-tapered portion and the bottom surface of the first base film 116 is larger than an angle between the side surface 116s of the tapered portion and the bottom surface of the first base film 116.

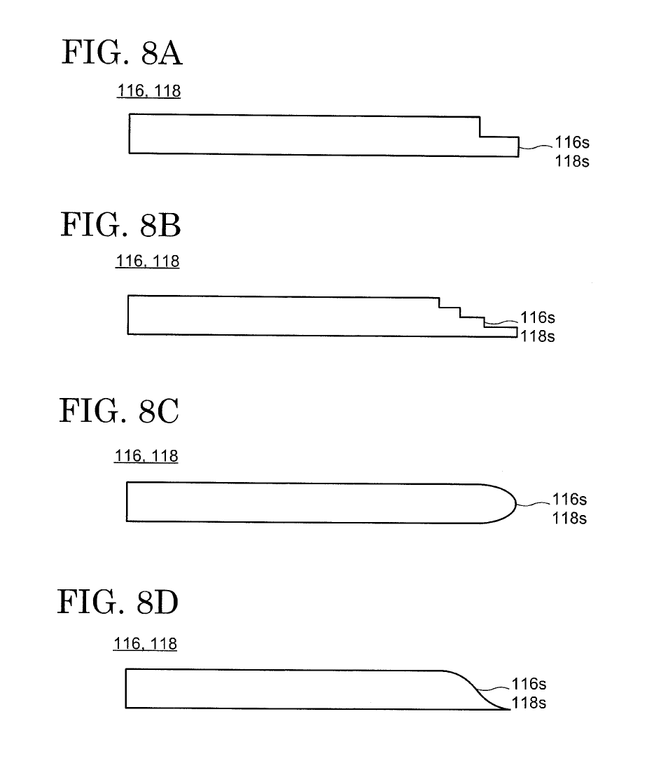

The shapes of the tapered portions of the first base film 116 and the second base film 118 are not limited to the aforementioned shapes. As shown in FIG. 4A, the inclined side surfaces 116s and 118s of the tapered portions may be each composed of a single plane. Alternatively, the tapered portions may be arranged so as to be thinned stepwise as shown in a cross-sectional view of FIG. 8A. In this case, the tapered portions may have a plurality of steps as shown in a cross-sectional view of FIG. 8B.

Alternatively, the first base film 116 and the second base film 118 may be configured so that the side surfaces 116s and 118s of the tapered portions are each expressed by a curve in the cross section. In this case, the tapered portions may have a round shape as shown in FIG. 8C, or the curves representing the side surfaces 116s and 118s of the tapered portions in the cross section may each have an inflection point as shown in FIG. 8D.

As described in the Second Embodiment for a manufacturing method of the display device 100, the use of the first base film 116 and the second base film 118 having the aforementioned shapes increases a manufacturing yield and reliability of the display device 100. This is due to the following reasons.

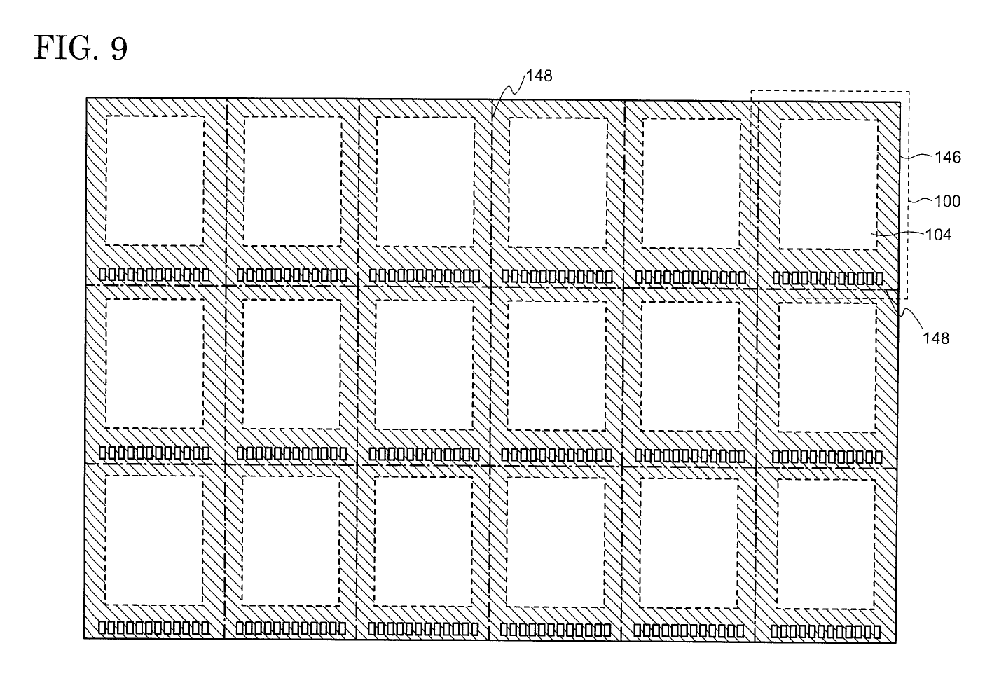

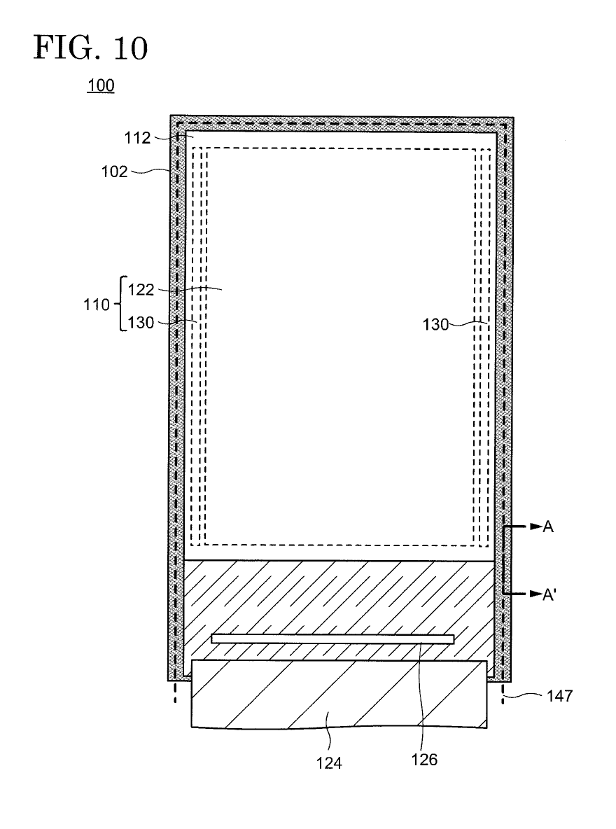

The plurality of display devices 100 are generally fabricated over a large-size substrate (mother glass) 146 as shown in FIG. 9. For example, a schematic drawing is shown in FIG. 9 for a case where eighteen display devices 100 are fabricated over a single mother glass 146. In a manufacturing process, the mother glass is divided along dividing lines 148, giving the individual display devices 100. After the mother glass 146 is divided, the IC chip 126 and the connector 124 are connected to the display device 100. FIG. 10 shows a state where the IC chip 126, the connector 124, and the cap film 112 as well as the first base film 116 and the second base film 118 which are not illustrated are connected to the display device 100 in the developed state. After that, trimming is conducted on the display device 100 so that the display device 100 is processed to have its final size. Trimming is carried out along a trimming line 147 by using a cutter or the like.

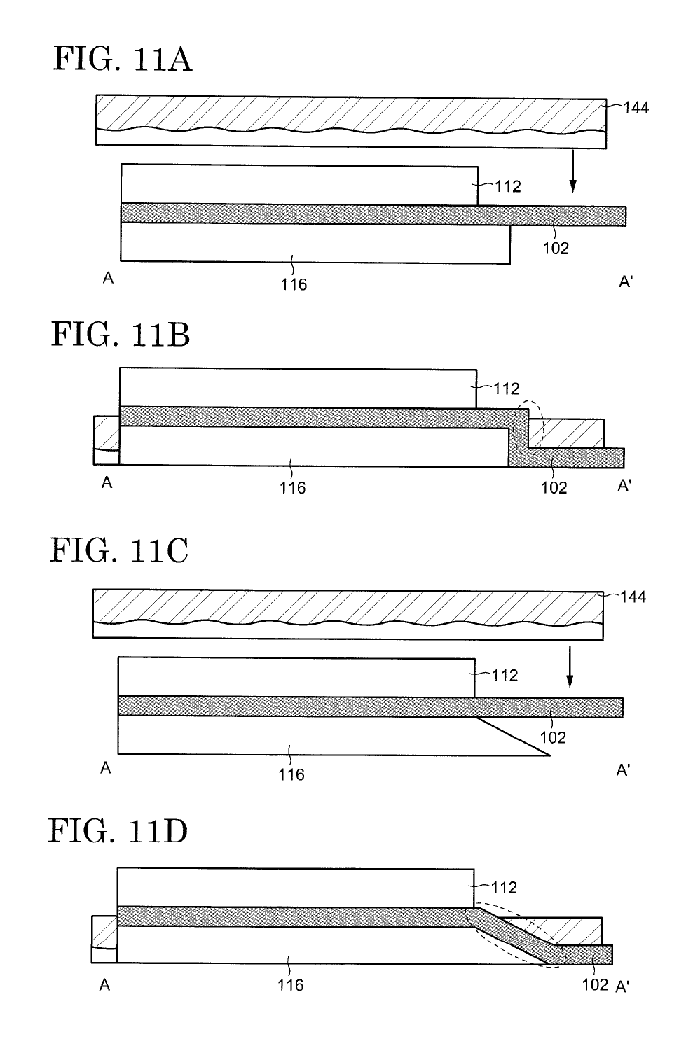

Variation in shape of the flexible substrate 102 during trimming is explained by using cross-sectional views (FIG. 11A to FIG. 11D) along a dotted line A-A′ of FIG. 10. As shown in FIG. 11A, if the trimming is carried out by pressing a cutter 114 from over the first base film 116 without the tapered portion, the flexible substrate 102 is bent at a right angle at at least two positions because the first base film 116 receives the pressure from the cutter 114 (see the region surrounded by a dotted ellipse in FIG. 11B). Therefore, a large strain is generated in the flexible substrate 102, resulting in a crack in the flexible substrate 102. The crack is readily caused in a periphery of the flexible substrate 102, and then grows inward. A crack initially generated in the flexible substrate 102 induces generation of cracks in a variety of insulating films and wirings (e.g., wirings 134) close to the initially generated crack. As a result, a sealing structure may be destroyed or disconnection of wirings may occur, and the function as a display device is lost. Note that, although not illustrated, the phenomenon described above may similarly occur in the case where the second base film 118 does not possess the tapered portion.

In contrast, as shown in FIG. 11C and FIG. 11D, when the tapered portion is provided to both or one of the edge portion of the first base film 116 and the edge portion of the second base film 118, the bending angle can be significantly reduced even if the flexible substrate 102 receives pressure from the cutter 144 and is bent. Hence, strain in the flexible substrate 102 can be decreased, by which generation of the cracks can be prevented or suppressed. Accordingly, a manufacturing yield of the display device 100 can be improved, and reliability thereof can be increased.

### Second Embodiment

In the present embodiment, a manufacturing method of the display device 100 is explained. An explanation of the contents described in the First Embodiment may be omitted.

The manufacturing process of the display device 100 is divided into a pre-process and a post-process. In the pre-process, the element layer 110, the wirings 134, the terminals 132, and the like are formed over the mother glass 146 by which a fundamental structure as a display device is structured. The post-process includes division of the mother glass 146, connection of the IC chip 126 and the connector 124, formation of the cap film 112, the first base film 116, and the second base film 118, and trimming. In the present embodiment, an explanation is given by using an example in which a light-emitting element is included as a display element.

### 1. Pre-Process

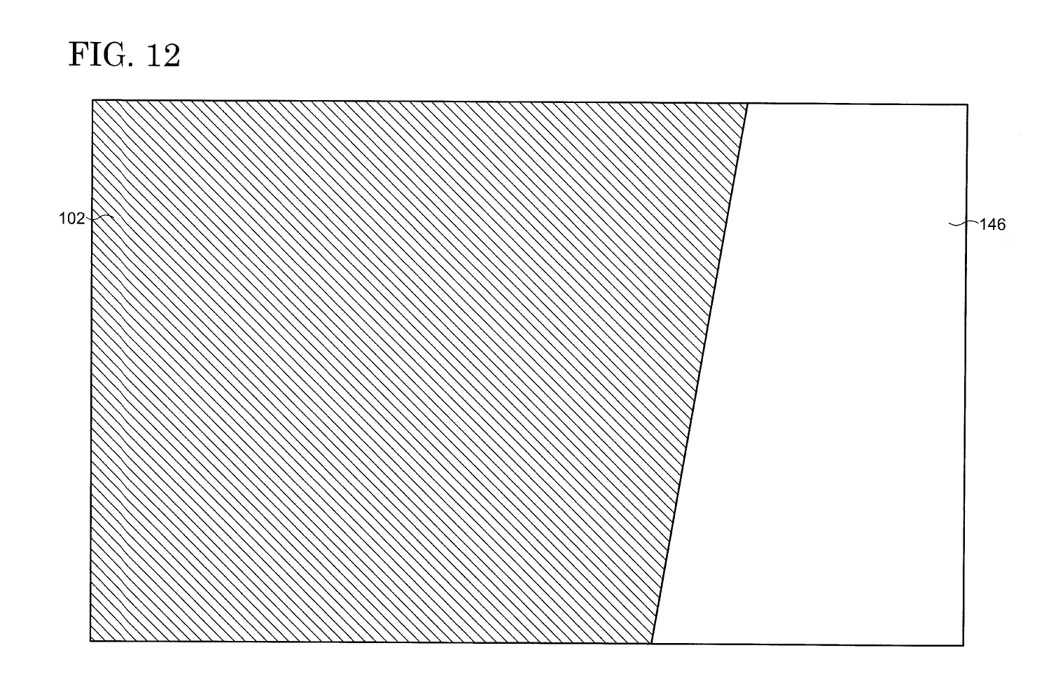

First, the flexible substrate 102 is formed over the mother glass 146 (FIG. 12). The mother glass 146 may include glass, and a size and thickness thereof may be arbitrarily selected. For example, a glass plate having a size of 68 cm×88 cm, 110 cm×130 cm, 150 cm×185 cm, or 220 cm×250 cm can be used as the mother glass 146. A thickness of the mother glass 146 can be arbitrarily selected from a range from 0.1 mm to 10 mm and typically 0.5 mm to 0.7 mm.

The flexible substrate 102 is an insulating film and may include a material selected from polymer materials exemplified by a polyimide, a polyamide, a polyester, and a polycarbonate. The flexible substrate 102 can be formed by applying a wet-type film-formation method such as a printing method, an ink-jet method, a spin-coating method, and a dip-coating method or a lamination method, for example. When the flexible substrate 102 is positioned over the mother glass 170, the flexible substrate 102 can be regarded as a polymer film fixed over the mother glass 170 because the mother glass 170 does not have flexibility. The mother glass 146 also functions as a supporting substrate for supporting the flexible substrate 102.

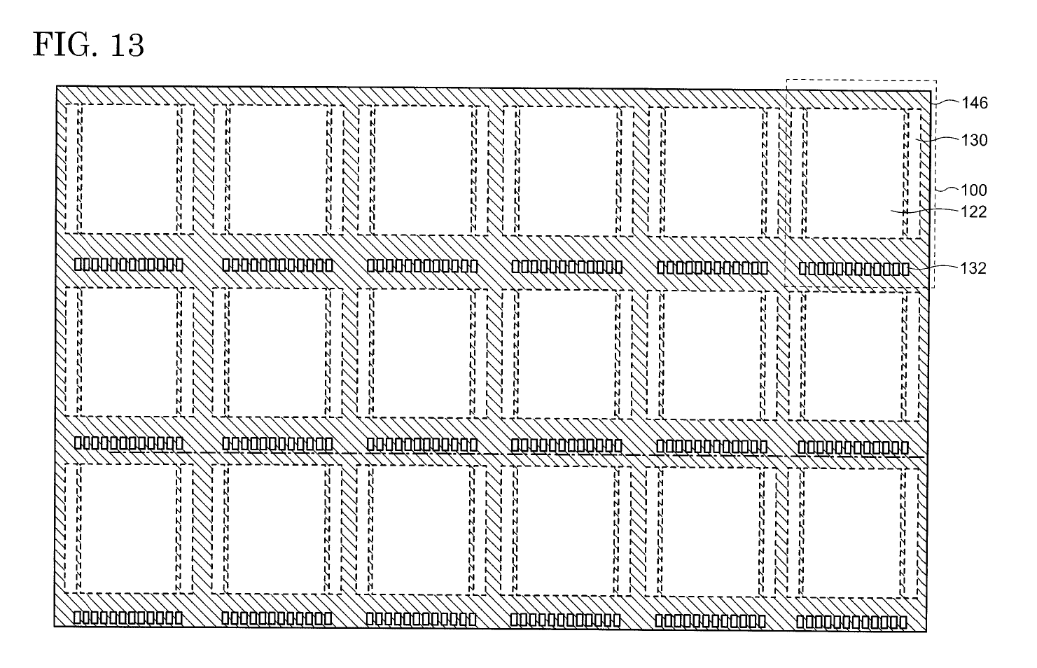

A layout for the case where eighteen display devices 100 are fabricated over the mother glass 146 is shown in FIG. 13. Here, a mode is illustrated where a total of eighteen display devices 100 arranged in three rows and six columns are formed over one mother glass 146. The number of the display devices 100 prepared over one mother glass 146 is not limited and is determined in view of size and shape of the mother glass 146 and the display device 100.

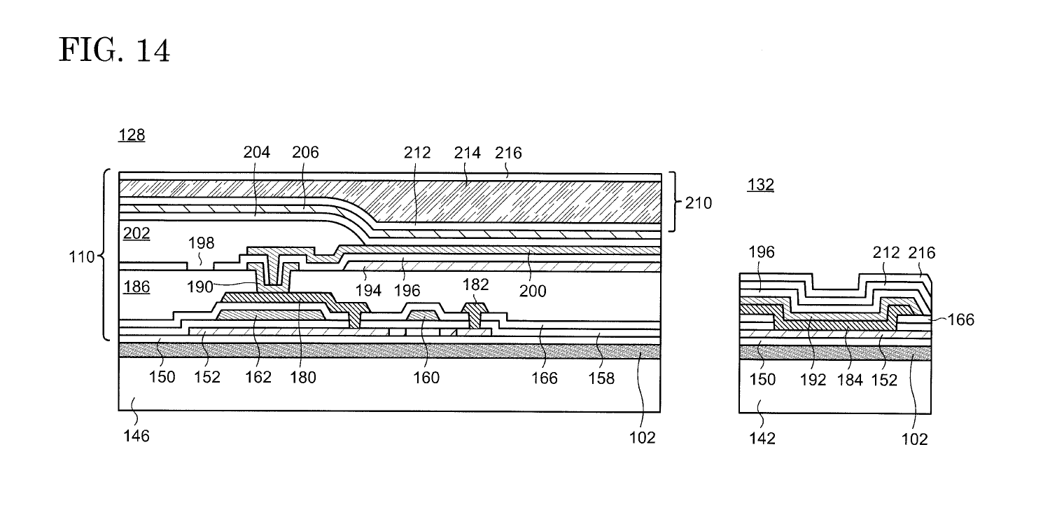

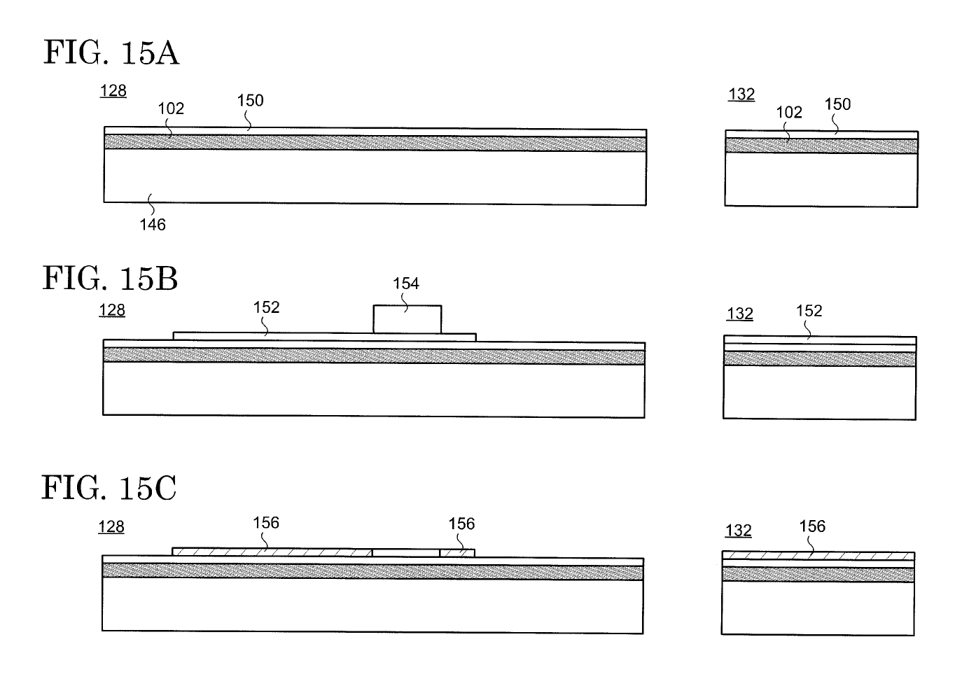

An example of a cross-sectional structure of the pixel 128 and the terminal 132 in the display region 122 formed in the pre-process is shown in FIG. 14. Hereinafter, the explanation of the pre-process is given by using this example with reference to FIG. 15A to FIG. 20B. FIG. 15A to FIG. 20B are schematic cross-sectional views of a part of the pixel 128 and the terminal 132.

An undercoat 150 is prepared over the flexible substrate 102 (FIG. 15A). The undercoat 150 may include a silicon-containing inorganic compound (silicon oxide, silicon nitride, silicon oxynitride, silicon nitride oxide, and the like) and may be formed with a chemical vapor deposition method (CVD method), a sputtering method, or the like so as to have a single-layer or stacked-layer structure. The undercoat 150 can be formed in both regions in which the pixel 128 and the terminal 132 are formed.

Next, a semiconductor films 152 is formed (FIG. 15B). The semiconductor film 152 may include silicon, germanium, an oxide (semiconductor oxide) exhibiting semiconductor properties, and the like. When the semiconductor film 152 contains silicon, the semiconductor film 152 may be formed by using silane gas as a raw material with a CVD method. Crystallization may be carried out by performing a heating treatment or applying light such as a laser on the obtained amorphous silicon. When the semiconductor film 152 contains an oxide semiconductor, the semiconductor film 152 can be formed with a target including an oxide semiconductor by utilizing a sputtering method.

Next, a resist mask 154 is formed over the semiconductor film 152 to cover a portion in which a channel region is to be formed, and then doping of the semiconductor film 152 with impurities is carried out (first doping). As impurities, phosphorous and nitrogen imparting a n-type conductivity or boron and aluminum imparting a p-type conductivity may be used. With this process, impurity regions are formed (FIG. 15C). Note that the semiconductor film 152 is also formed and doped with impurities in the region where the terminal 132 is to be fabricated in the present embodiment. However, the semiconductor film 152 may not be formed in this region.

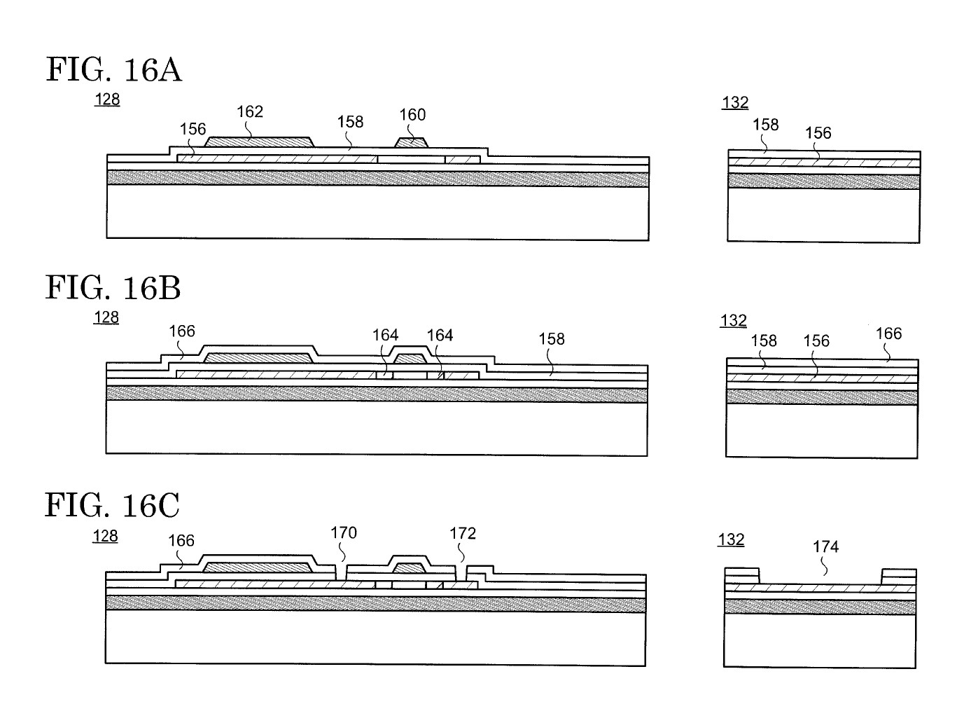

After removing the resist mask 154, a gate insulating film 158 is formed to cover the semiconductor film 152 (FIG. 16A). The gate insulating film 158 may include a silicon-containing inorganic compound and may be formed by applying a CVD method or a sputtering method so as to have a single-layer structure or a stacked-layer structure. The insulating film 158 may be also formed in the region in which the terminal 132 is to be fabricated.

Next, a capacitor electrode 162 and a gate 160 are prepared over the gate insulating film 158 (FIG. 16A). The capacitor electrode 162 and the gate 160 may include a metal such as titanium, aluminum, copper, molybdenum, tungsten, and tantalum or an alloy thereof and may be formed to have a single-layer or stacked-layer structure. For example, a structure may be employed in which a metal with a relatively high conductivity, such as aluminum and copper, is sandwiched by a metal with a relative high melting point, such as titanium, tungsten, and molybdenum. The capacitor electrode 162 and the gate 160 may be formed simultaneously. Thus, they can exist in the same layer.

Next, an interlayer film 166 is formed over the capacitor electrode 162 and the gate 160 (FIG. 16B). Similar to the undercoat 150 and the gate insulating film 158, the interlayer film 166 may include a silicon-containing inorganic compound and can be formed by applying a CVD method or a sputtering method. The interlayer film 166 may be also formed in the region where the terminal 132 is to be prepared.

In this state, doping of the semiconductor film 152 is performed again by using the gate 160 as a mask. The dose amount at this time is lower than that in the first doping. With this process, a channel region overlapping with the gate 160 and low-concentration impurity regions 164 between the channel region and the impurity regions 156 are formed. This doping may be carried out before forming the interlayer film 166.

Next, etching is performed on the interlayer film 166 and the gate insulating film 158 to form openings 170 and 172 reaching the semiconductor film 152 (FIG. 16C). The openings can be formed by conducting plasma etching in a gas including a fluorine-containing hydrocarbon, for example. At this time, the interlayer film 166 and the gate insulating film 158 are partly removed in the region where the terminal 132 is to be formed, resulting in the formation of an opening 174.

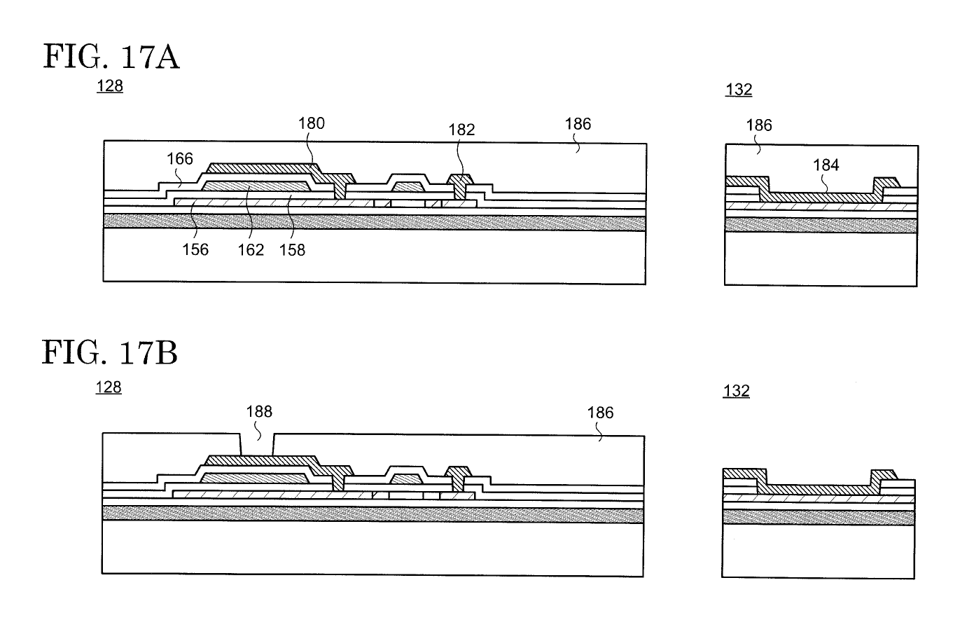

Next, a metal film is formed to cover the openings 170, 172, and 174 and processed with etching to form a source 180, a drain 182, and a first terminal electrode 184 (FIG. 17A). With this process, a transistor is fabricated in the pixel 128. Note that a part of the source 180 overlaps with the capacitor electrode 162, and a capacitor is formed by the part of the source 180 overlapping with the capacitor electrode 162, the interlayer film 166, the capacitor electrode 162, the gate insulating film 158, and the impurity region 156.

Next, a leveling film 186 is formed over the whole of the mother glass 146 (FIG. 17A). The leveling film 186 is also an insulating film and may be formed with an organic compound. As an organic compound, a polymer material such as an epoxy resin, an acrylic resin, a polyimide, a polyamide, a polyester, a polycarbonate, and a polysiloxane is represented. The leveling film 186 can be formed by applying a spin-coating method, an ink-jet method, a printing method, a dip-coating method, or the like. After that, etching is performed on the leveling film 186 to form an opening portion 188 reaching the source 180 (FIG. 17B). At this time, the leveling film 186 is removed in the region where the terminal 132 is to be formed.

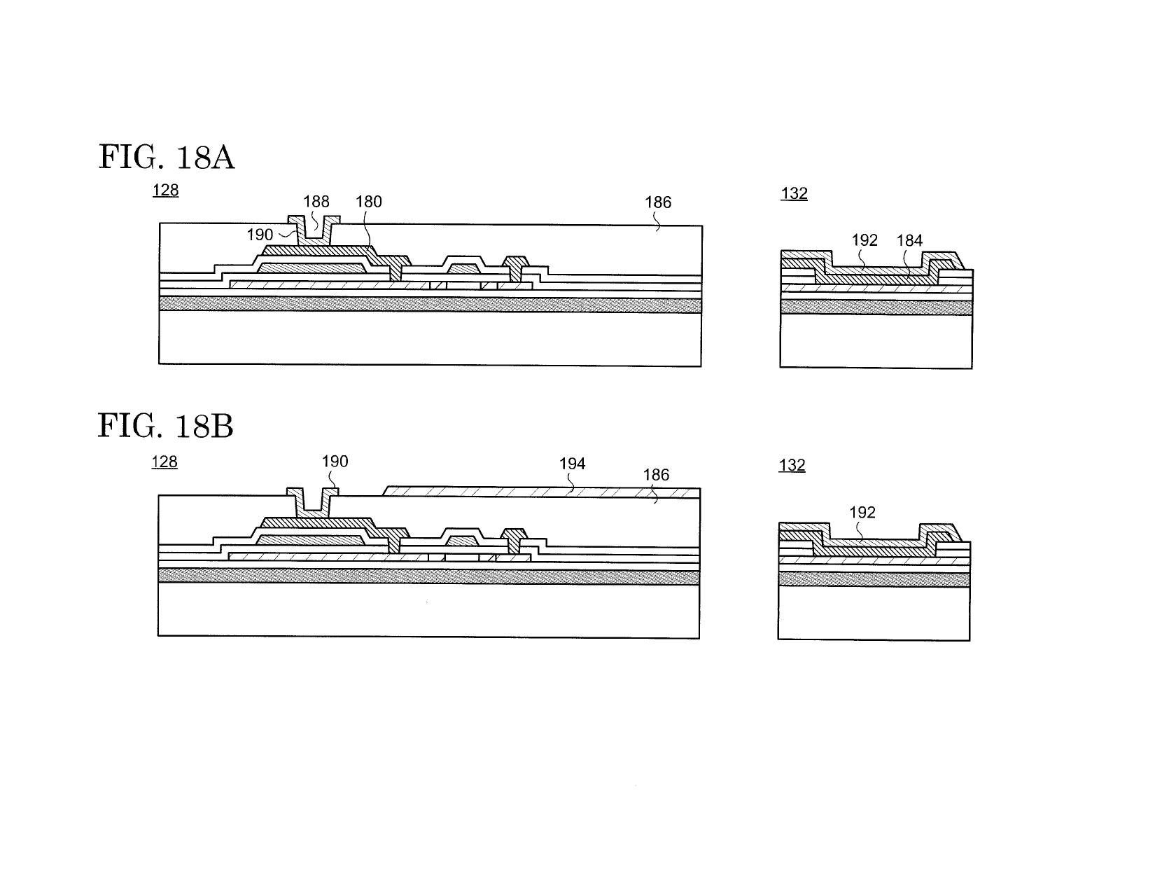

Next, a connection electrode 190 and a second terminal electrode 192 are formed so as to respectively cover the opening portion 188 exposing the source 180 and the first terminal electrode 184 (FIG. 18A). These electrodes can be formed by sputtering a conductive oxide such as indium-tin oxide (ITO) and indium-zinc oxide (IZO). With this process, the connection electrode 190 and the second terminal electrode 192 are electrically connected to the source 180 and the first terminal electrode 184, respectively. The formation of the connection electrode 190 and the second terminal electrode 192 prevents oxidation or deterioration of the source 180 and the first terminal electrode 184 in the following processes, by which an increase in contact resistance at their surfaces can be inhibited.

Next, a supplementary capacitor electrode 194 is formed over the leveling film 186 (FIG. 18B). The supplementary capacitor electrode 194 may include a metal or an alloy usable in the gate 160, the source 180, and the drain 182 and may be formed by applying a sputtering method or a CVD method. The supplementary capacitor electrode 194 may have a single-layer structure or a stacked-layer structure.

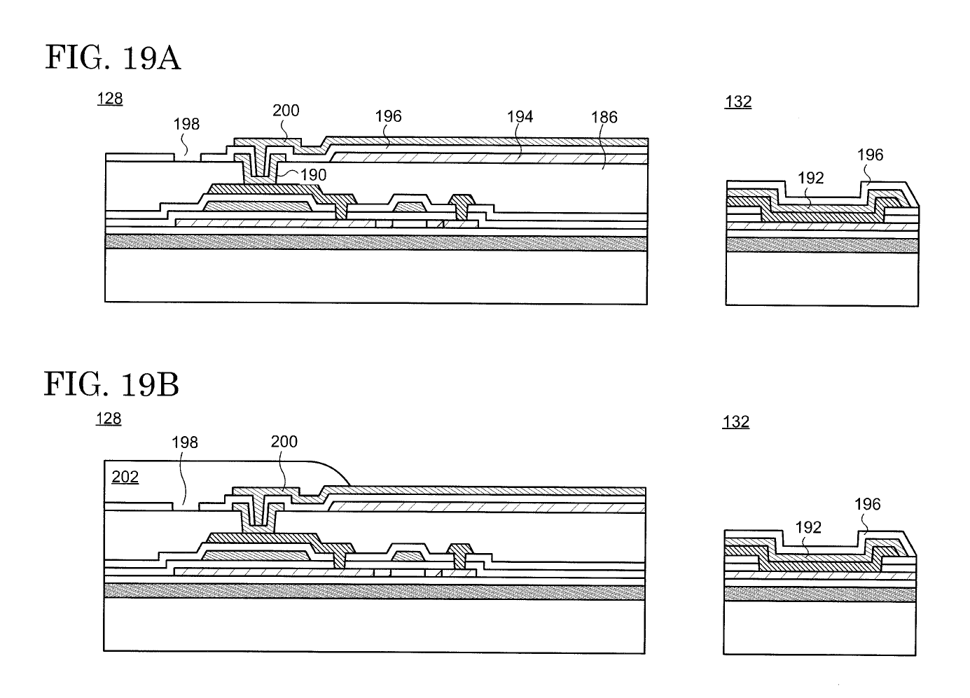

After that, an insulating film 196 is formed so as to cover the connection electrode 190 and the supplementary capacitor electrode 194 (FIG. 19A). The insulating film 196 may be formed so as to cover the second terminal electrode 192. The insulating film 196 may also include a silicon-containing inorganic compound and can be formed by applying a CVD method or a sputtering method. Note that the insulating film 196 has an opening exposing a part of a bottom surface of the connection electrode 190. A first electrode 200 of the light-emitting element and the connection electrode 190 are electrically connected in this opening. An opening 198 exposing the leveling film 186 may be further formed in the insulating film 196. This opening 198 serves as an opening for releasing impurities such as water from the leveling film 186.

Next, the first electrode 200 is formed so as to be in contact with the connection electrode 190 and cover the supplementary capacitor electrode 194. When the light emission from the light-emitting element is extracted from a side opposite to the first electrode 200, the first electrode 200 is configured to reflect visible light. In this case, a metal with a high reflectance, such as silver and aluminum, or an alloy thereof is used for the first electrode 200. A film of a conductive oxide having a light-transmitting property may be formed over a film including the metal or alloy. When the light emission from the light-emitting element is extracted through the first electrode 200, the first electrode 200 may be formed with a conductive oxide having a light-transmitting property. A supplementary capacitor is formed by the supplementary capacitor electrode 194, the insulating film 196, and the first electrode 200 to contribute to maintenance of a potential of the gate 160.

Next, a partition wall 202 is formed so as to cover an edge portion of the first electrode 200 and the opening 198 (FIG. 19B). Steps caused by the first electrode 200 and the like are absorbed and the first electrodes 200 of the adjacent pixels 128 are electrically insulated by the partition wall 202. The partition wall 202 can be formed by using a polymer material such as an epoxy resin and an acrylic resin with a wet-type film-formation method. Impurities mixed in the leveling film 186 are released through the opening 198 and the partition wall 202 in a heating process for forming the partition wall 202.

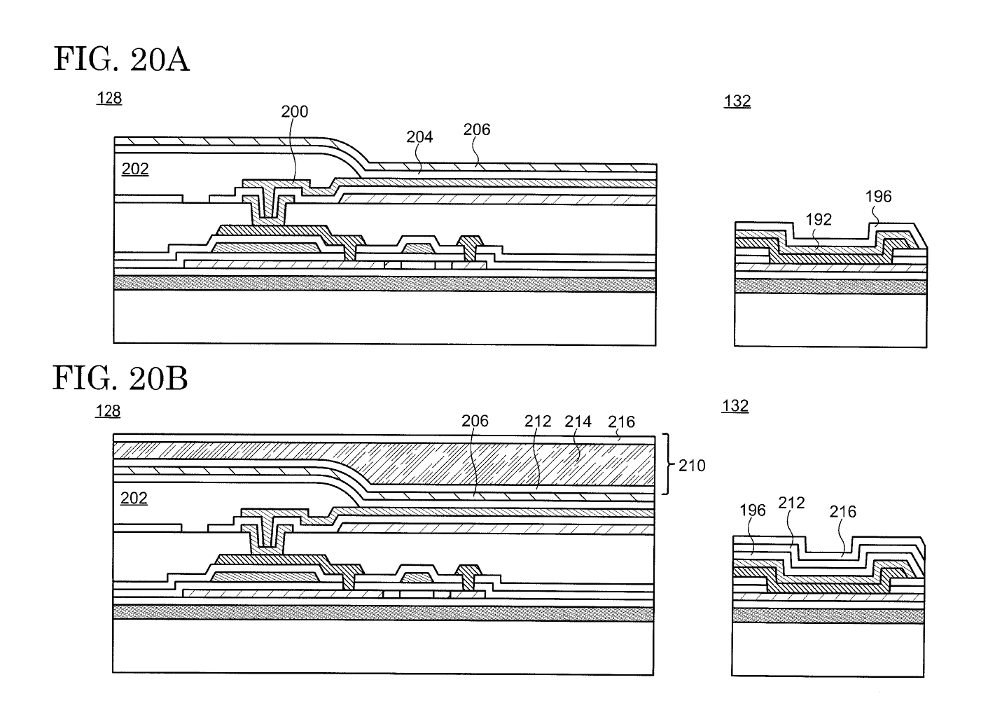

Next, an EL layer 204 and a second electrode 206 of the light-emitting element are formed so as to cover the first electrode 200 and the partition wall 202 (FIG. 20A). The EL layer 204 includes an organic compound and may be formed by applying a wet-type film-formation method or a dry-type film-formation method such as evaporation. Although not illustrated, the structure of the EL layer 204 is arbitrarily determined, and the EL layer 204 can be structured with a plurality of layers with different functions. For example, the EL layer 204 may be formed by appropriately combining a carrier-injection layer, a carrier-transporting layer, an emission layer, a carrier-blocking layer, and the like. The EL layer 204 may have different structures between the adjacent pixels 128.

When the light-emission from the light-emitting element is extracted through the first electrode 200, a metal such as aluminum, magnesium, and silver or an alloy thereof can be used for the second electrode 206. On the other hand, when the light-emission from the light-emitting element is extracted through the second electrode 206, a conductive oxide or the like with a light-transmitting property, such as ITO, may be used for the second electrode 206. Alternatively, a film of the metal may be formed at a thickness which allows visible light to pass therethrough. In this case, a conductive oxide having a light-transmitting property may be further stacked. Through the above processes, the light-emitting element is fabricated.

A passivation film 210 may be formed, as an optional structure, over the light-emitting element in order to protect the light-emitting element. For example, the passivation film 210 in which a first layer 212 including a silicon-containing inorganic compound, a second layer 214 including an organic compound, and a third layer 216 including a silicon-containing inorganic compound are stacked may be formed over the second electrode 206 as shown in FIG. 20B.

The first layer 212 can be formed by applying a CVD method or a sputtering method. The second layer 214 may include, as an organic compound, a polymer material such as an acrylic resin, a polysiloxane, a polyimide, and a polyester and may be formed with a wet-type film-formation method. Alternatively, the second layer 214 may be formed by atomizing or gasifying oligomers serving as a raw material of the aforementioned polymer material under a reduced pressure, spraying the first layer 212 with the oligomers, and then polymerizing the oligomers. Moreover, as shown in FIG. 20B, the second layer 214 may be formed at a thickness which allows depressions and projections caused by the partition wall 202 to be absorbed and a flat surface to be provided. The third layer 216 may include a material usable in the first layer 212 and can be formed with a method applicable to the formation of the first layer 212.

In the case where the passivation film 210 is provided, the first layer 212 and the third layer 216 may be formed to cover the terminal 132 (FIG. 20B). With the above steps, the pre-process is completed, and the element layer 110 structuring the display region 122 including the pixels 128 and the driver circuits 130 is formed. In the present specification and claims, the element layer 110 means the stacked structure from the undercoat 150 to the passivation film 210.

### 2. Post-Process

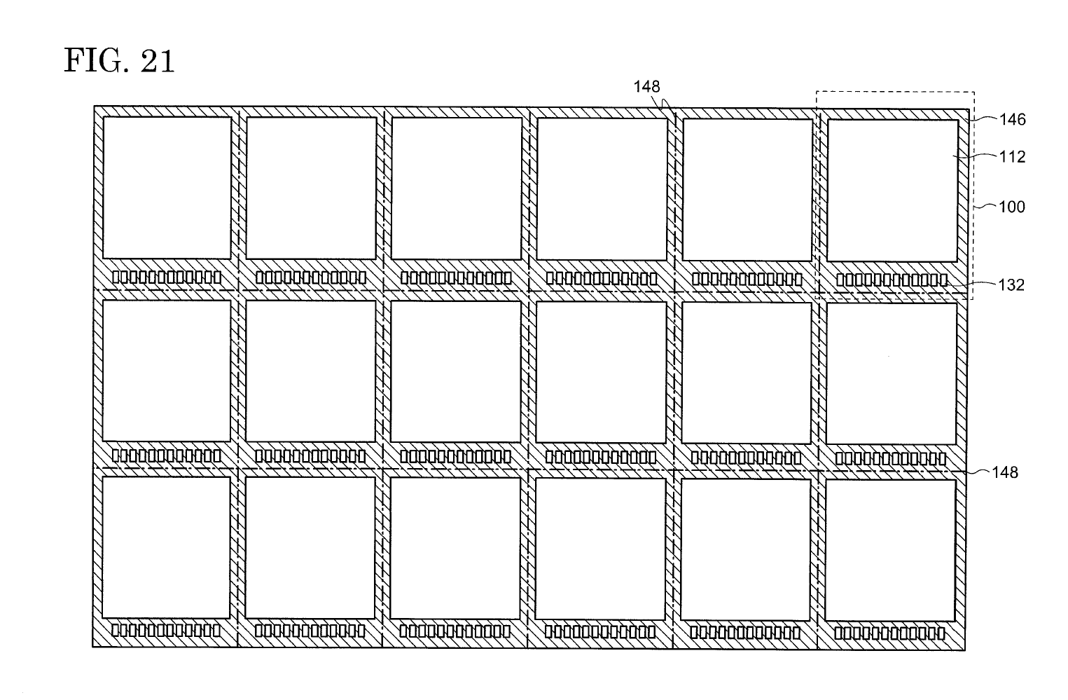

In the post-process, the cap film 112 is first formed so as to cover the active region 104, that is, the display region 122 and the driver circuits 130 (FIG. 21). The cap film 112 may include a polymer material exemplified by a polyester such as poly(ethylene terephthalate) and poly(ethylene naphthalate), a polyolefin such as polyethylene and polypropylene, a polycarbonate, a poly(acrylic ester), and the like. The cap film 112 can be formed with a lamination method or a wet-type film-formation method. A fluorine-containing polymer film such as poly(vinylidene fluoride) (PVDF) and polytetrafluoroethylene or a polymer film with low gas permeability, such as poly(vinylidene chloride) may be provided on a surface of the cap film 112. In FIG. 21, the cap film 112 is independently disposed in every display device 100. However, the cap film 112 may be formed across the plurality of display devices 100.

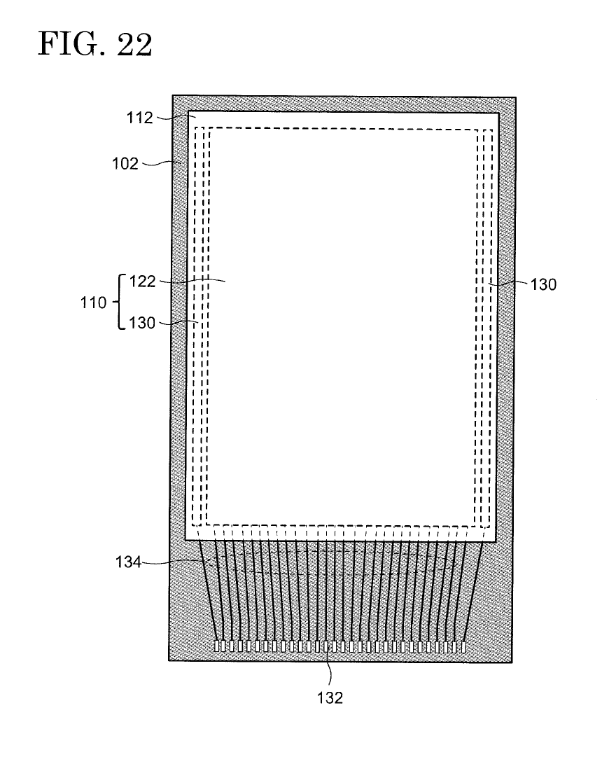

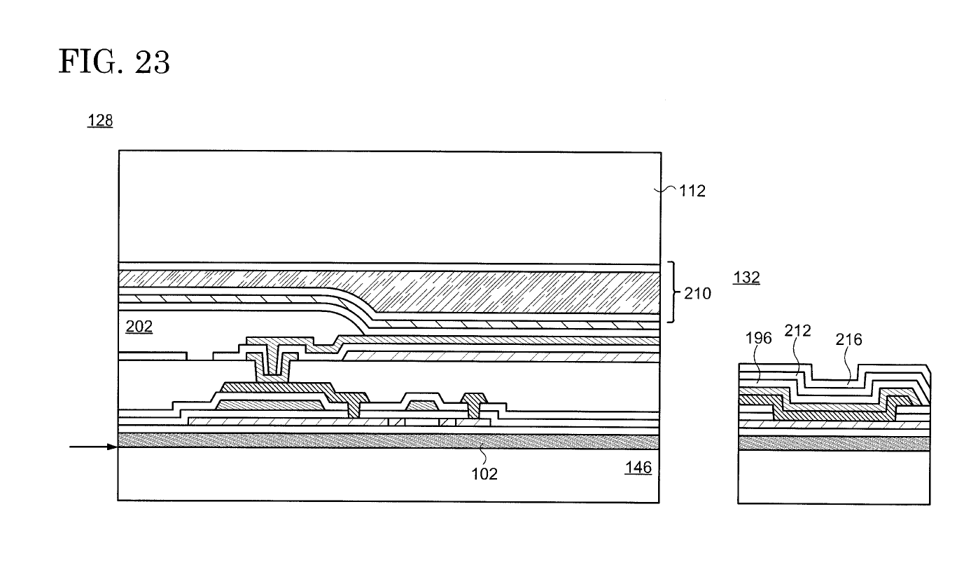

After that, the mother glass 146 is divided along the dividing lines 148 into the individual display devices 100. The division can be conducted by using a scriber or the like. A top view and a cross-sectional view of the display device 100 after division are shown in FIG. 22 and FIG. 23, respectively. As shown in FIG. 22, the cap film 112 may cover a part of the wirings 134. When the cap film 112 is independently provided in each display device 100, the whole of the cap film 112 overlaps with the flexible substrate 102. The cap film 112 is illustrated so as to be in contact with the passivation film 210 in FIG. 23. However, the cap film 112 may be fixed over the passivation film 210 via an adhesion layer.

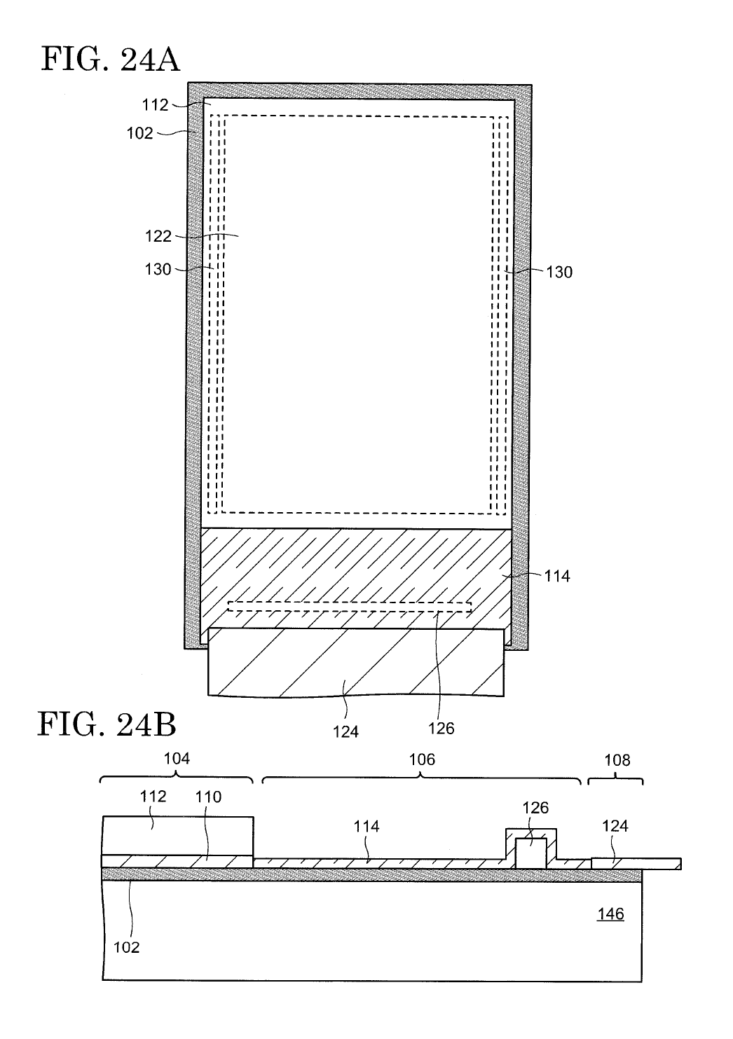

Next, the IC chip 126 and the connector 124 are connected to the wirings 134 and the terminals 132, respectively (FIG. 24A, FIG. 24B). Specifically, the insulating films over the terminals 132, that is, the insulating film 196, the first layer 212, and the third layer 216 are removed with dry etching or ashing to expose the second terminal electrodes 192. Although not shown, the insulating films are also removed over the terminals connected to the IC chip 126. After that, the IC chip 126 and the connector 124 are connected by using an anisotropic conductive film.

After that, the resin film 114 is formed as shown in FIG. 24A and FIG. 24B. The resin film 114 can be formed by using a polymer material such as an epoxy resin and an acrylic resin. As described above, the resin film 114 may cover a part of the connector 124.

Next, the first base film 116 and the second base film 118 are formed. Specifically, light irradiation is performed from a side of the mother glass 146 by using a light source such as a laser-light source or a flash lamp to decrease adhesion between the mother glass 146 and the flexible substrate 102. After that, the mother glass 146 is physically peeled off along an interface indicated by an arrow in FIG. 23, that is, an interface between the mother glass 146 and the flexible substrate 102. With this process, the bottom surface of the flexible substrate 102 is exposed.

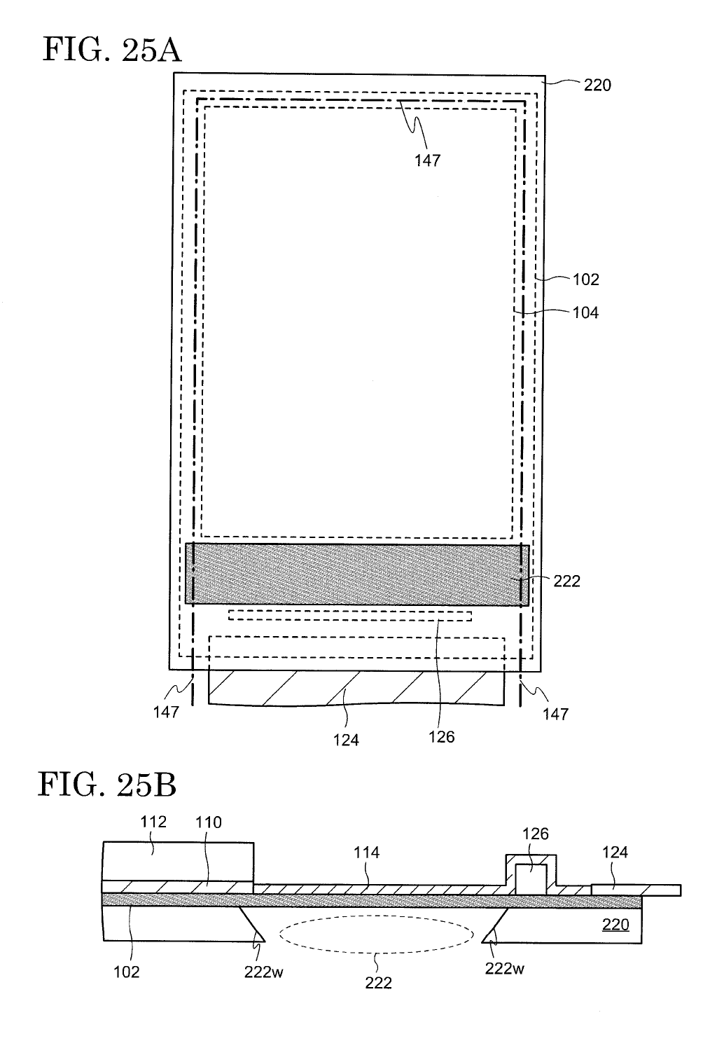

Next, as shown in FIG. 25A and FIG. 25B, a base film 220 having an opening portion 222 is fixed to the bottom surface of the flexible substrate 102. The base film 220 can be fixed with a lamination method. At this time, an adhesion layer may be used. The base film 220 may include a material usable in the cap film 112. The bottom surface of the flexible substrate 102 is exposed in the opening portion 222 of the base film 220. The base film 220 is disposed so that the opening portion 222 overlaps with at least a part of the wirings 134. The base film 220 shown in FIG. 25A and FIG. 25B is provided so that the opening portion 222 does not overlap with the IC chip 126 and the connector 124. However, the opening portion 222 may overlap with a part of the IC chip 126 and the connector 124.

Here, a shape of sidewalls 222w of the opening portion 222 is reflected in the shape of the edge portions of the first base film 116 and the second base film 118. Therefore, the sidewalls 222w of the opening portion 222 are configured so that an opening edge of the base film 220 has a tapered shape.

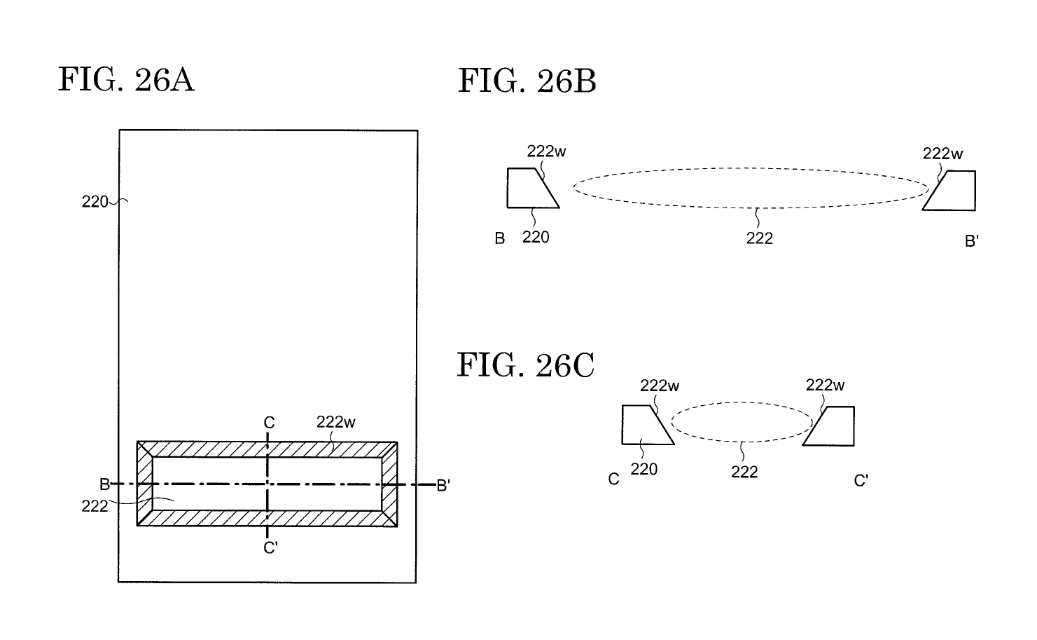

A top view of the base film 220 of an embodiment of the present invention is shown in FIG. 26A, and cross-sectional views along dotted lines B-B′ and C-C′ of FIG. 26A are shown in FIG. 26B and FIG. 26C, respectively. As shown in FIG. 26A to FIG. 26C, the opening portion 222 may have a polygonal shape such as a rectangular shape, and the base film 220 may be configured so that the sidewalls 222w are inclined from an upper surface of the base film 220. Therefore, an area of the opening portion 222 is different between at the upper surface and an undersurface of the base film 220, and the area at the upper surface (that is, a surface in contact with the bottom surface of the flexible substrate 102) is larger than the area at the other surface. An incline of the sidewalls 222w can be arbitrarily adjusted and determined in view of the inclines of the side surface 116s of the first base film 116 and the side surface 118s of the second base film 118.

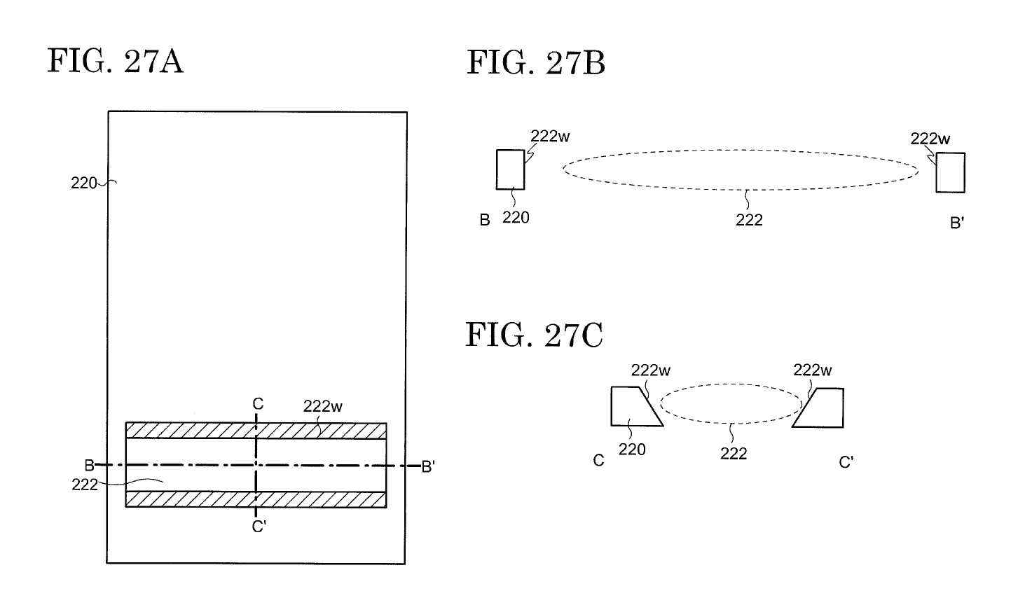

In the example shown in FIG. 26A to FIG. 26C, all of the sidewalls 222w of the opening portion 222 are inclined from the upper surface of the base film 220. However, it is not necessary that all of the sidewalls 222w included in the opening portion 222 are inclined from the upper surface of the base film 220 as long as at least one of the sidewalls 222w is inclined. For example, a pair of sidewalls 222w facing each other may be inclined while the other pair of sidewalls 222w may be perpendicular to the upper surface of the base film 220 as shown in FIG. 27A to FIG. 27C. In this case, although the pair of inclined sidewalls 222w may be parallel or perpendicular to a short side of the display device 100, the opening portion 222 is formed so that the sidewalls 222w intersecting the trimming line 147 described below are inclined.

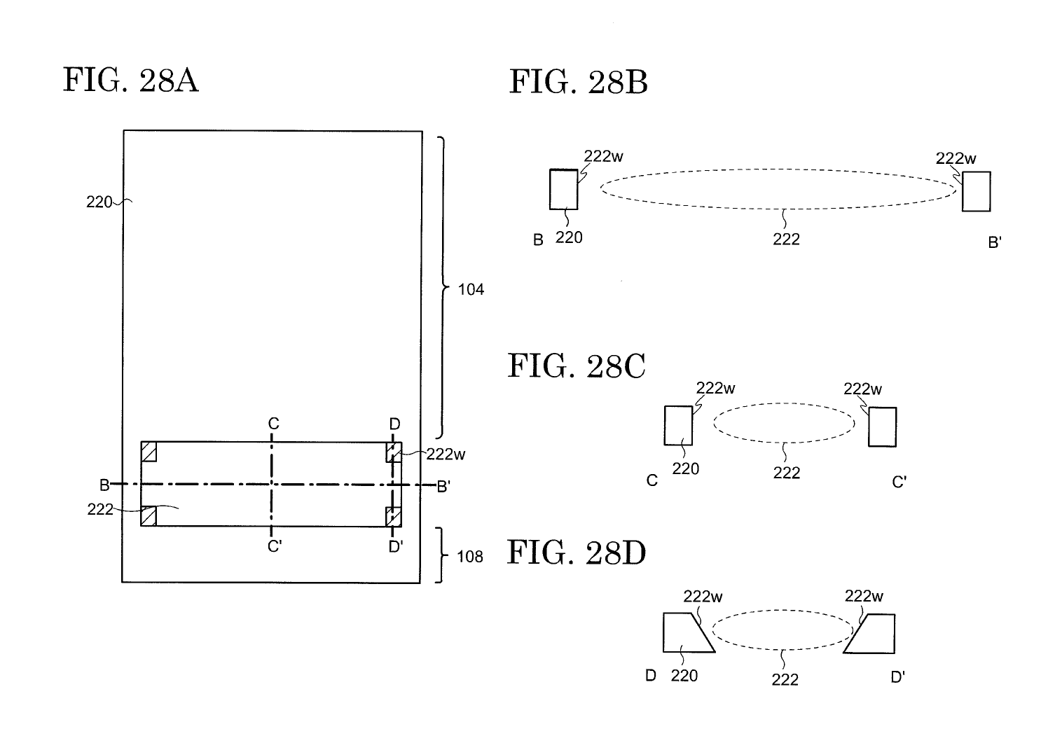

Alternatively, as shown in FIG. 28A to FIG. 28D, a part of the sidewall 222w is inclined and the other part of the sidewall 222w may be perpendicular to the upper surface of the base film 220. In other words, the opening portion 222 may be formed so that the sidewall 222w perpendicular to the upper surface of the base film 222 is sandwiched by two inclined sidewalls 222w. In this case, two inclined sidewalls 222w are provided so as to intersect the trimming line 147. With respect to the sidewalls 222w of the opening portion 222 close to the active region 104, the sidewall 222w perpendicular to the upper surface of the base film 220 is closer to the active region 104 than the tips of the inclined sidewalls 222w. On the other hand, with respect to the sidewalls 222w of the opening portion 222 close to the terminal region 108, the sidewall 222w perpendicular to the upper surface of the base film 220 is closer to the terminal region 108 than the tips of the inclined sidewalls 222w. Additionally, the shape of the opening portion 222 at the bottom surface of the base film 220 is a polygon having 5 or more vertexes (12 vertexes in the case of the shape shown in FIG. 28A).

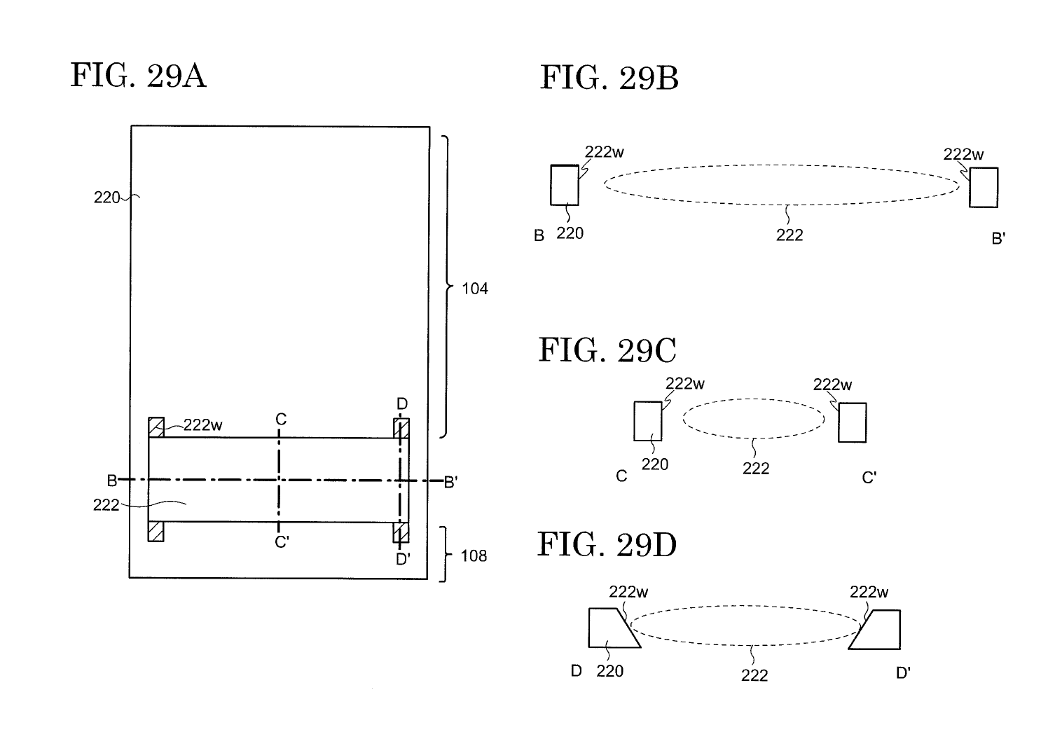

When the sidewall 222w perpendicular to the upper surface of the base film 220 is sandwiched by two inclined sidewalls 222w, the opening portion 222 may be formed so that a straight line formed by the tips of the inclined sidewalls 222w is located on a plane formed by the sidewall 222w perpendicular to the upper surface of the base film 220 as shown in FIG. 29A to FIG. 29D. In this case, the shape of the opening portion 222 at the bottom surface of the base film 220 can be a rectangle.

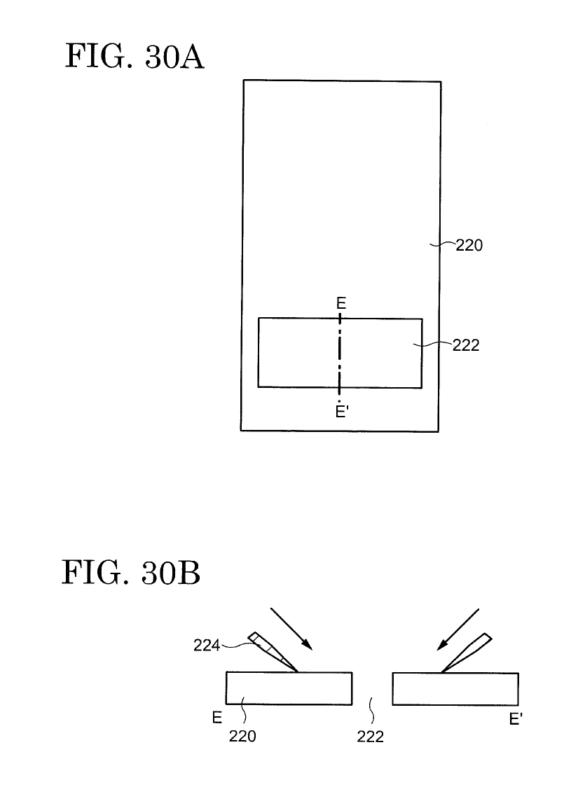

The sidewalls 222w having such a shape can be formed by processing the base film 220 as follows. For example, as shown in FIG. 30A, the opening portion 222 is first prepared so that all of the sidewalls 222w are perpendicular to the upper surface of the base film 220. The opening portion 222 with such a shape can be prepared by trenching the base film 220 by using a cutter whose edge provides a rectangular shape. After that, as shown in a cross-sectional view (FIG. 30B) along a dotted line E-E′ of FIG. 30A, a cutter 224 is applied to the base film 220 in a direction inclined from the upper surface of the base film 220 from a vicinity of the opening portion 222 to remove a part of the base film 220, by which the base film 220 shown in FIG. 27A to FIG. 27C can be prepared.

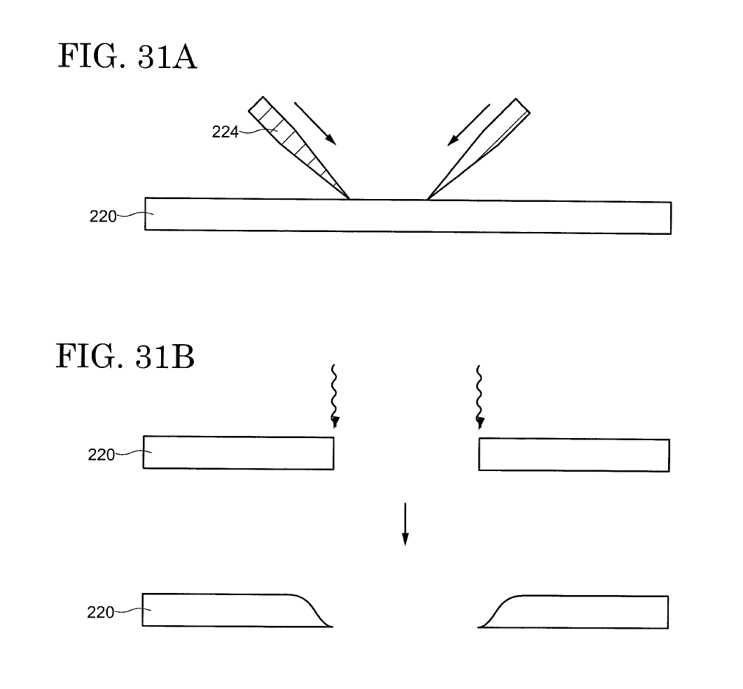

Alternatively, as shown in FIG. 31A, the opening portion 222 may be formed by applying the cutter 224, in a direction inclined from the upper surface of the base film 220, to the base film 220 in which the opening portion 222 is not formed. Note that, when the inflection point is provided to the cross-sectional shape of the side surfaces 116s and 118s of the first base film 116 and the second base film 116 as shown in FIG. 8D, the opening portion 222 is first formed so that the sidewalls 222w are perpendicular to the upper surface of the base film 222, and then a part of the base film 220 is melted by heating an upper portion of the sidewalls 222w by means of irradiation of laser light or the like as shown in FIG. 31B.

After bonding the base film 220 to the bottom surface of the flexible substrate 102, trimming is performed along the trimming line 147 (FIG. 25A). The trimming may be conducted by using a cutter 144 whose edge provides a U-shape (see FIG. 11D). At this time, the trimming is carried out so that the trimming line 147 intersects at least two points of the opening portion 222. With this process, the peripheral portion of the flexible substrate 102 is trimmed, and the base film 220 is simultaneously divided into the first base film 116 and the second base film 118 spaced from each other. In the example shown in the present embodiment, the first base film 116 and the second base film 118 each possess the tapered portions on the side surfaces 116s and 118s facing each other, and the tapered portions thereof are inclined from the first base film 116 and the second base film 118, respectively.

Through these processes, the display device 100 is manufactured.

As described in the First Embodiment, at least one of the edge portion of the first base film 116 and the edge portion of the second base film 118 of the display device 100 has the tapered portion. The display device 100 having such a feature can be manufactured by using the base film 220 having the opening portion 220 with the inclined sidewalls 222w. Therefore, probability of the generation of a crack in the flexible substrate 102 and other insulators and wirings during the trimming process is significantly decreased. As a result, a display device with high reliability can be manufactured at a high yield.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a substrate comprising:
a display region including a plurality of pixels;
a terminal region including a terminal; and
a wiring region between the display region and the terminal region, the wiring region including a wiring extending from the terminal to the display region;
a first base film on an opposite side of the substrate from the plurality of pixels and under the display region; and
a second base film on the opposite side of the substrate from the plurality of pixels and under the terminal region, the second base film being spaced from the first base film,
wherein the first base film has a side surface facing the second base film and having a tapered portion.

2. The display device according to claim 1, wherein the side surface having the tapered portion is inclined from a surface of the first base film opposite to the substrate at an acute angle.

3. The display device according to claim 2, wherein the side surface having the tapered portion is a plane.

4. The display device according to claim 2, wherein, in a cross section of the first base film along a line extending from the display region to the terminal region, the side surface having the tapered portion is expressed by a curve.

5. The display device according to claim 4, wherein the curve has an inflection point.

6. The display device according to claim 1, further comprising a cap film on an opposite side of the substrate from the first base film and over the display region, wherein the side surface having the tapered portion overlaps with a side surface of the cap film.

7. The display device according to claim 1,
wherein the side surface further comprises:
a second tapered portion; and
a non-tapered portion between the tapered portion and the second tapered portion, and
a first angle between the side surface where the non-tapered portion is located and a main surface of the first base film opposite to the substrate is larger than a second angle between the side surface where the tapered portion is located and the main surface.

8. The display device according to claim 7, wherein the side surface where the tapered portion is located is inclined from the main surface at an acute angle.

9. The display device according to claim 7, wherein the second angle is a right angle.

10. The display device according to claim 1, wherein the second base film has a side surface facing the first base film and having a tapered portion.

11. A display device comprising:
a flexible substrate comprising a first region including a plurality of pixels and a second region spaced from the first region, the first region overlapping with the second region;
a first base film in the first region and on an opposite side of the flexible substrate from the plurality of pixels; and
a second base film in the second region and on the opposite side of the flexible substrate from the plurality of pixels,
wherein the first base film and the second base film are sandwiched between the first region and the second region, and
the first base film has a side surface overlapping with the second region and having a tapered portion.

12. The display device according to claim 11,
wherein the flexible substrate further comprises a third region connecting the first region and the second region,
the third region is bent, and
the side surface faces the third region.

13. The display device according to claim 11, wherein the side surface having the tapered portion is inclined from a surface of the first base film opposite to the flexible substrate at an acute angle.

14. The display device according to claim 13, wherein the side surface having the tapered portion is a plane.

15. The display device according to claim 12, wherein, in a cross section of the first base film in a direction from the first region to the second region via the third region, the side surface having the tapered portion is expressed by a curve.

16. The display device according to claim 15, wherein the curve has an inflection point.

17. The display device according to claim 11, further comprising a cap film on an opposite side of the substrate from the first base film and over the first region, wherein the side surface having the tapered portion overlaps with a side surface of the cap film.

18. The display device according to claim 11,
wherein the side surface further comprises:
a second tapered portion; and
a vertical portion between the tapered portion and the second tapered portion, and
the side surface where the vertical portion is located is perpendicular to a main surface of the first base film, the main surface being in contact with the flexible substrate.

19. The display device according to claim 18, wherein the side surface where the second tapered portion is located is inclined from a surface of the first base film opposite to the flexible substrate at an acute angle.

20. The display device according to claim 11, wherein the second base film has a side surface overlapping with the side surface of the first base film and having the tapered portion.
